(19) United States
(12) Patent Application Publication
(10) Pub. No.: US 2026/0068473 A1
(43) Pub. Date: Mar. 5, 2026

(54) DISPLAY DEVICE

(71) Applicant: LG Display Co., Ltd., Seoul (KR)

(72) Inventors: SungJin KIM, Paju-si (KR); MiKyung LEE, Paju-si (KR); Subin YOO, Paju-si (KR)

(73) Assignee: LG Display Co., Ltd., Seoul (KR)

(21) Appl. No.: 19/275,619

(22) Filed: Jul. 21, 2025

(30) Foreign Application Priority Data
Aug. 30, 2024 (KR) 10-2024-0117536

(51) Int. Cl. H10K 59/38; G06F 3/041; G06F 3/044; G09G 3/3233; H10K 59/40

(52) U.S. Cl. CPC H10K 59/38; G06F 3/0412; H10K 59/40; G06F 3/044; G06F 2203/04111; G09G 3/3233; G09G 2300/0842; G09G 2354/00

(57) ABSTRACT

A display can include a substrate, a plurality of light emitting elements disposed on the substrate, and a plurality of color filters disposed to overlap the plurality of light emitting elements. At least one of the plurality of color filters can include light scattering particles for scattering light incident thereon.

### CROSS-REFERENCE TO RELATED APPLICATION

This application claims priority to Korean Patent Application No. 10-2024-0117536, filed in the Republic of Korea on Aug. 30, 2024, which is hereby expressly incorporated by reference for all purposes as if fully set forth herein.

### BACKGROUND

### Field

Embodiments of the disclosure relate to a display device.

### Description of the Related Art

Display devices are applied to various electronic devices, such as TVs, mobile phones, laptops, and tablets. Display devices include organic light emitting displays (OLEDs), which are self-emissive, and liquid crystal displays (LCDs), which require a separate light source.

Meanwhile, the organic light emitting display device can include an anode, a cathode, and an organic light emitting layer disposed therebetween. In this case, as a metal material with high reflectivity is used to form the cathode and various lines, external light incident on the display device can be reflected by the metal material. The reflected external light diffracts or interferes with each other, and is emitted back to the outside. For example, rainbow mura can be caused by diffraction and interference of external reflected light, and can be perceived as a rainbow-like spread of colors on a screen of the display device, thereby reducing screen visibility of the display device.

### SUMMARY OF THE DISCLOSURE

Embodiments of the disclosure can provide a display device having a light scattering layer capable of mitigating rainbow mura.

Embodiments of the disclosure can provide a display device having a color filter capable of mitigating rainbow mura.

Embodiments of the disclosure can provide a display device having a color filter capable of preventing color mixing.

Embodiments of the disclosure can provide a display device including a light emitting element with advanced reliability.

A display panel according to embodiments of the disclosure can comprise a substrate, a plurality of light emitting elements disposed on the substrate, and a plurality of color filters disposed to overlap the plurality of light emitting elements. At least one of the plurality of color filters can include light scattering particles for scattering light incident thereon.

For example, two or more color filters of the plurality of color filters can include light scattering particles. A weight percent of light scattering particles included in one of the two or more color filters can be equal to or larger than a weight percent of light scattering particles included in another color filter of the two or more color filters.

A display device according to embodiments of the disclosure can comprise a substrate, a plurality of subpixels disposed on the substrate, a first light emitting element disposed on the substrate and included in a first subpixel of the plurality of subpixels, a second light emitting element disposed on the substrate and included in a second subpixel of the plurality of subpixels, a third light emitting element disposed on the substrate and included in a third subpixel of the plurality of subpixels, and a light scattering layer disposed on the first light emitting element, the second light emitting element, and the third light emitting element.

According to aspects of the disclosure, the light scattering layer can include a first area overlapping the first light emitting element, a second area overlapping the second light emitting element, and a third area overlapping the third light emitting element. At least one of the first area, the second area, and the third area can include light scattering particles for scattering light incident thereon.

For example, a height of each of the first area, the second area, and the third area can vary depending on whether the light scattering particles are included.

As another example, when two or more areas of the first area, the second area, and the third area include the light scattering particles, a weight percent of the light scattering particles included in one of the two or more areas can be different from a weight percent of the light scattering particles included in another area of the two or more areas.

According to embodiments of the disclosure, there can be provided a display device having a light scattering layer capable of mitigating rainbow mura.

According to embodiments of the disclosure, there can be provided a display device having a color filter capable of mitigating rainbow mura.

According to embodiments of the disclosure, there can be provided a display device having a color filter capable of preventing color mixing.

According to embodiments of the disclosure, there can be provided a display device including a light emitting element with advanced reliability.

According to embodiments of the disclosure, there can be provided a high-efficiency display device capable of implementing a desired level or more of brightness with low power consumption by not including a polarizer in a display panel.

According to embodiments of the disclosure, a light scattering layer can be applied to a color filter. Thus, as a light scattering layer need not be formed through a separate process, a display device capable of process optimization can be provided.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 illustrates a display device according to embodiments of the disclosure;

FIG. 2 illustrates a display panel according to an embodiment of the disclosure;

FIG. 3 is a partial cross-sectional view illustrating a display panel according to embodiments of the disclosure;

FIG. 4 illustrates a portion of a display area of a display panel according to embodiments of the disclosure;

FIGS. 5 to 8 are cross-sectional views illustrating a plurality of subpixels taken along line I-I′ of FIG. 4 in a display panel according to embodiments of the disclosure;

FIG. 9 illustrates a type of light scattering particles included in a display panel according to embodiments of the disclosure;

FIGS. 10 to 12 are cross-sectional views illustrating a plurality of subpixels taken along line I-I′ of FIG. 4 in a display panel according to embodiments of the disclosure;

FIG. 13 illustrates a type of light scattering particles included in a display panel according to embodiments of the disclosure;

FIGS. 14 to 16 are cross-sectional views illustrating a plurality of subpixels taken along line I-I′ of FIG. 4 in a display panel according to embodiments of the disclosure;

FIG. 17 is a cross-sectional view illustrating a plurality of subpixels including a functional color filter taken along line I-I′ of FIG. 4 in a display panel according to embodiments of the disclosure; and

FIG. 18 is a cross-sectional view illustrating a plurality of subpixels taken along line I-I′ of FIG. 4 in a display panel according to embodiments of the disclosure.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the disclosure are described in detail with reference to the accompanying drawings. All the components of each display device according to all embodiments of the disclosure are operatively coupled and configured.

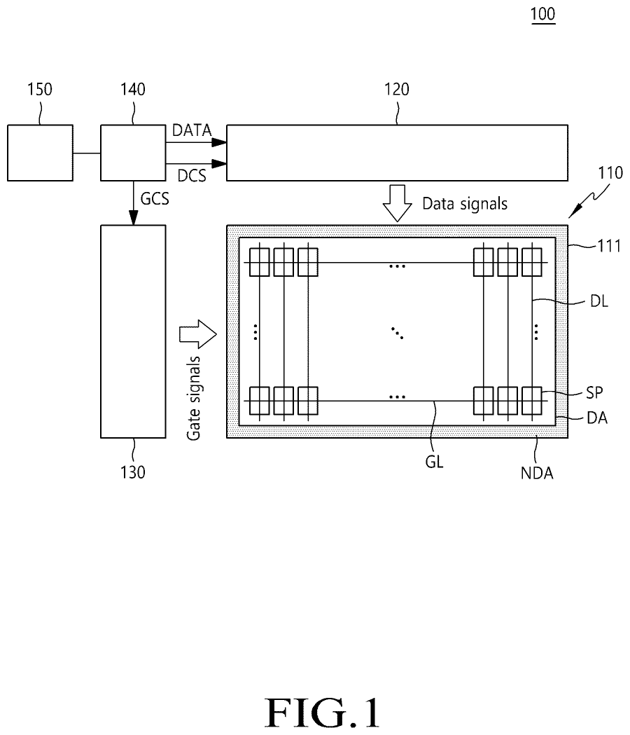

FIG. 1 illustrates a display device according to embodiments of the disclosure.

Referring to FIG. 1, a display device 100 according to embodiments of the disclosure can include a display panel 110 and display driving circuits, as components for displaying images. The display driving circuit can be a circuit for driving the display panel 110. The display driving circuits can include a data driving circuit 120, a gate driving circuit 130, and a controller 140, but are not limited thereto.

The display panel 110 can include a substrate 111 and a plurality of subpixels SP disposed on the substrate 111.

The substrate 111 can include a display area DA and a non-display area NDA.

The display area DA is an area where images can be displayed, and can also be referred to as an active area. A plurality of subpixels SP for image display can be disposed in the display area DA.

The non-display area NDA is an area where no image is displayed and can be an area outside the display area DA. The non-display area NDA can also be referred to as a bezel (or bezel area). The non-display area NDA can include a pad area where the driving circuit is connected or bonded (or attached).

The display device 100 according to embodiments of the disclosure can be a self-emission display device in which the display panel 110 emits light by itself, but embodiments of the disclosure are not limited thereto. When the display device 100 according to the embodiments of the disclosure is a self-emission display device, each of the plurality of subpixels SP can include a light emitting element.

For example, the display device 100 according to embodiments of the disclosure can be an organic light emitting diode display in which the light emitting element is implemented as an organic light emitting diode (OLED). As another example, the display device 100 according to embodiments of the disclosure can be an inorganic light emitting display device in which the light emitting element is implemented as an inorganic material-based light emitting diode. As another example, the display device 100 according to embodiments of the disclosure can be a quantum dot display device in which the light emitting element is implemented as a quantum dot which is self-emission semiconductor crystal. As another example, the display device 100 according to embodiments of the disclosure can be a micro LED display device or a mini LED display device.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors, but embodiments of the disclosure are not limited thereto.

Various types of signal lines for driving a plurality of subpixels SP can be disposed on the substrate 111 of the display panel 110. For example, various types of signal lines can include a plurality of data lines DL transferring data signals (also referred to as data voltages or image signals) and a plurality of gate lines GL transferring gate signals (also referred to as scan signals).

The plurality of data lines DL and the plurality of gate lines GL can cross each other. Each of the plurality of data lines DL can be disposed to extend in the column direction. Each of the plurality of gate lines GL can be disposed to extend in the row direction. According to embodiments of the disclosure, the column direction and the row direction can be relative directions. For example, the column direction can be the row direction depending on the viewpoint, and the row direction can be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto. In embodiments of the disclosure, the angle between the row direction and the column direction can be 90 degrees or can an angle different from 90 degrees. Further, in embodiments of the disclosure, the row direction can be referred to as a first direction, and the column direction can be referred to as a second direction.

The data driving circuit 120 can be a circuit for driving the plurality of data lines DL, and can output data signals to the plurality of data lines DL.

The data driving circuit 120 can receive digital image data DATA from the controller 140 and can convert the received digital image data DATA into analog data signals (or also referred to as data voltages) and output them to the plurality of data lines DL.

For example, the data driving circuit 120 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110, but embodiments of the disclosure are not limited thereto.

The data driving circuit 120 can be connected to one side (e.g., an upper or lower side) of the display panel 110. As another example, depending on the driving scheme or the panel design scheme, a plurality of data driving circuits 120 can be connected with both the sides (e.g., both the upper and lower sides) of the display panel 110, or two or more of the four sides of the display panel 110.

The data driving circuit 120 can be connected outside the display area DA of the display panel 110, but as another example, the data driving circuit 120 can be disposed in the display area DA of the display panel 110.

The gate driving circuit 130 is a circuit for driving the plurality of gate lines GL, and can output gate signals to the plurality of gate lines GL.

The gate driving circuit 130 can receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS from the controller 140, generate gate signals including a section having the first gate voltage and a section having the second gate voltage for a predetermined time (e.g., one frame time), and supply the generated gate signals to the plurality of gate lines GL. For example, the turn-on level voltage can be a high level voltage, and the turn-off level voltage can be a low level voltage. As another example, the turn-on level voltage can be a low level voltage, and the turn-off level voltage can be a high level voltage.

In the display device 100 according to embodiments of the disclosure, the gate driving circuit 130 can be embedded, in a gate in panel (GIP) type, in the display panel 110, but embodiments of the disclosure are not limited thereto. When the gate driving circuit 130 is of the gate in panel type, the gate driving circuit 130 can be formed on the substrate 111 of the display panel 110 during the manufacturing process of the display panel 110.

For example, the gate driving circuit 130 can be disposed in the non-display area NDA of the display panel 110.

As another example, the gate driving circuit 130 can be disposed in the display area DA of the display panel 110. For example, the gate driving circuit 130 can be disposed in a first partial area in the display area DA (e.g., a left area or a right area in the display area DA). As another example, the gate driving circuit 130 can be disposed in a first partial area in the display area DA (e.g., a left area or right area in the display area DA) and a second partial area (e.g., a right area or left area in the display area DA). As another example, the gate driving circuit 130 can be disposed over the entire display area DA.

When the gate driving circuit 130 is disposed in the display area DA of the display panel 110, the gate driving circuit 130 can vertically overlap the subpixels SP disposed in the display area DA. For example, the gate driving circuit 130 can vertically overlap the light emitting elements and transistors included in the subpixels SP disposed in the display area DA. The gate driving circuit 130 can vertically overlap a plurality of light emitting elements and a plurality of transistors included in a plurality of subpixels SP disposed in the display area DA. The gate driving circuit 130 can include a plurality of transistors. Each of the plurality of transistors included in the gate driving circuit 130 can include an active layer including a first semiconductor material, and each of the plurality of transistors included in the subpixels SP can include an active layer including a second semiconductor material. For example, the first semiconductor material and the second semiconductor material can be substantially identical. As another example, the first semiconductor material and the second semiconductor material can be different from each other. For example, the first semiconductor material can be a silicon-based semiconductor material (e.g., low temperature poly silicon), and the second semiconductor material can be an oxide semiconductor material. For example, the active layer can be, but is not limited to, a semiconductor layer.

The controller 140 is a device for controlling the data driving circuit 120 and the gate driving circuit 130 and can control driving timings for the plurality of data lines DL and driving timings for the plurality of gate lines GL.

The controller 140 can supply a data driving control signal DCS to the data driving circuit 120 to control the data driving circuit 120 and can supply a gate driving control signal GCS to the gate driving circuit 130 to control the gate driving circuit 130.

The controller 140 can receive input image data from a host system 150 and supply digital image data DATA to the data driving circuit 120 based on the input image data.

The controller 140 can be implemented as a separate component from the data driving circuit 120, or the controller 140 and the data driving circuit 120 can be integrated into an integrated circuit (IC).

The controller 140 can be a timing controller used in display technology, a control device that can perform other control functions as well as the functions of the timing controller, or a control device other than the timing controller, or can be a circuit in the control device. The controller 140 can be implemented as various circuits or electronic components, such as an integrated circuit (IC), a field programmable gate array (FPGA), an application specific integrated circuit (ASIC), or a processor, but is not limited thereto.

The controller 140 can be mounted on a printed circuit board or a flexible printed circuit and can be electrically connected with the data driving circuit 120 and the gate driving circuit 130 through the printed circuit board or the flexible printed circuit.

The controller 140 can transmit/receive signals to/from the data driving circuit 120 according to one or more predetermined interfaces. The interface can include, e.g., a low voltage differential signaling (LVDS) interface, an embedded clock point-point interface (EPI), and a serial peripheral interface (SPI), but embodiments of the disclosure are not limited thereto.

To provide a touch sensing function as well as an image display function, the display device 100 according to embodiments of the disclosure can include a touch sensor and a touch sensing circuit that senses the touch sensor to detect whether a touch occurs by a touch object, such as a finger or pen, or the position of the touch.

The touch sensing circuit can include a touch driving circuit that drives and senses the touch sensor and generates and outputs touch sensing data and a touch controller that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit.

The touch sensor can be present in a touch panel form outside the display panel 110 or can be present inside the display panel 110. When the touch panel, in the form of a touch panel, exists outside the display panel 110, the touch panel is of an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate 111, together with signal lines and electrodes related to display driving, during the manufacturing process of the display panel 110.

The touch driving circuit can supply a touch driving signal to at least one of the plurality of touch electrodes and can sense at least one of the plurality of touch electrodes to generate touch sensing data.

The touch sensing circuit can perform touch sensing in a self-capacitance sensing scheme or a mutual-capacitance sensing scheme.

When the touch sensing circuit performs touch sensing in the self-capacitance sensing scheme, the touch sensing circuit can perform touch sensing based on capacitance between each touch electrode and the touch object (e.g., finger or pen). According to the self-capacitance sensing scheme, each of the plurality of touch electrodes can serve both as a driving touch electrode and as a sensing touch electrode. The touch driving circuit can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes. According to the mutual-capacitance sensing scheme, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single device. The touch driving circuit and the data driving circuit can be implemented as separate devices or as a single device.

The display device 100 can further include a power supply circuit for supplying various types of power to the display driver integrated circuit and/or the touch sensing circuit. The power supply circuit can supply various voltages and power voltages related to display driving to the display driving circuit or display panel 110.

The display device 100 according to embodiments of the disclosure can be a mobile terminal, such as a smart phone or a tablet, or a monitor or television (TV) in various sizes but, without limited thereto, can be a display in various types and various sizes capable of displaying information or images.

The display device 100 according to embodiments of the disclosure can further include an electronic device such as a camera (image sensor), a detection sensor, or the like. For example, the detection sensor can be a sensor that detects an object or a human body by receiving light such as infrared rays, ultrasonic waves, or ultraviolet rays, but embodiments of the disclosure are not limited thereto.

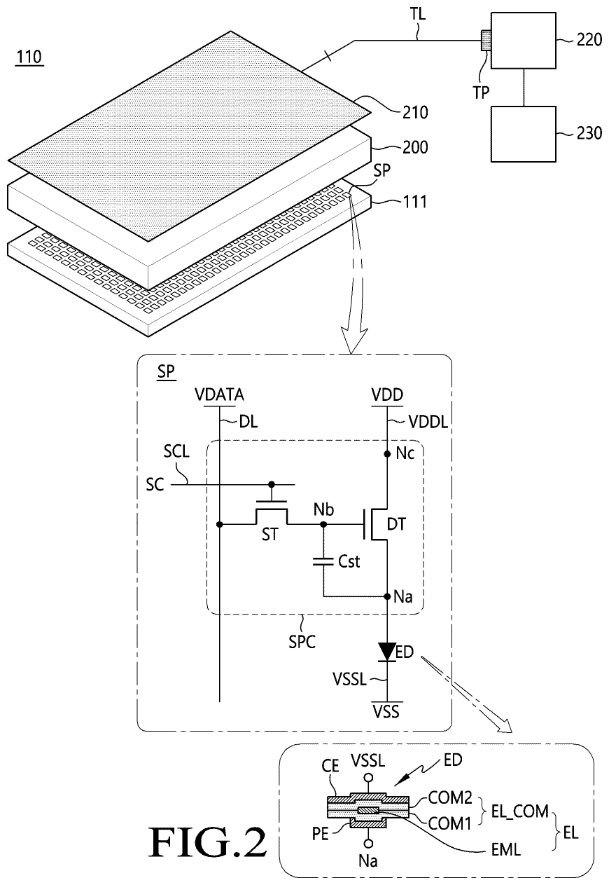

FIG. 2 illustrates a display panel 110 according to an embodiment of the disclosure.

Referring to FIG. 2, the display panel 110 can include a substrate 111, a plurality of subpixels SP disposed on the substrate 111 and an encapsulation layer 200 on the substrate 111. The encapsulation layer 200 can also be referred to as an encapsulation substrate or an encapsulation unit.

When the display device 100 according to embodiments of the disclosure is a self-luminous display device, each of the plurality of subpixels SP disposed on the substrate 111 can include a light emitting element ED and a subpixel circuit SPC for driving the light emitting element ED.

The subpixel circuit SPC can include a plurality of transistors and at least one capacitor for driving the light emitting element ED, but embodiments of the disclosure are not limited thereto. In the disclosure, the subpixel circuit SPC can drive the light emitting element ED by supplying a driving current to the light emitting element ED at a predetermined timing. The light emitting element ED can be driven by a driving current to emit light.

The plurality of transistors can include a driving transistor DT for driving the light emitting element ED and a scanning transistor ST that is turned on or off according to the scan signal SC.

The driving transistor DT can supply a driving current to the light emitting element ED.

The scanning transistor ST can be configured to control the electrical state of a corresponding node in the subpixel circuit SPC or to control the state or operation of the driving transistor DT.

The at least one capacitor can include a storage capacitor Cst for maintaining a constant voltage during a frame.

To drive the subpixel SP, a data signal VDATA as an image signal and a scan signal SC as a gate signal can be applied to the subpixel SP. Further, for driving the subpixel SP, a common driving signal including the driving voltage VDD and the base voltage VSS can be applied to the subpixel SP.

The light emitting element ED can include a pixel electrode PE, a light emitting unit EL, and a common electrode CE. The light emitting unit EL can be disposed between the pixel electrode PE and the common electrode CE.

For example, the pixel electrode PE can be an electrode disposed in each subpixel SP, and the common electrode CE can be an electrode commonly disposed in all the subpixels SP. For example, the pixel electrode PE can be an anode and the common electrode CE can be a cathode. As another example, the pixel electrode PE can be a cathode and the common electrode CE can be an anode. Hereinafter, for convenience of description, an example in which the pixel electrode PE is an anode and the common electrode CE is a cathode is described.

When the light emitting element ED is an organic light emitting element, the light emitting unit EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

The light emitting layer EML can be disposed for each subpixel SP. The common intermediate layer EL_COM can be commonly disposed across the plurality of subpixels SP, but embodiments of the disclosure are not limited thereto.

The light emitting layer EML can be disposed for each emission area (also referred to as a light emitting area). The common intermediate layer EL_COM can be commonly disposed across a plurality of emission areas and non-emission areas, but embodiments of the disclosure are not limited thereto. For example, the common intermediate layer EL_COM can be disposed in a portion of the non-display area NDA.

For example, the first common intermediate layer COM1 can include a hole injection layer HIL, an electron blocking layer EBL, and a hole transport layer HTL, but embodiments of the disclosure are not limited thereto. The second common intermediate layer COM2 can include an electron transport layer ETL, a hole blocking layer HBL, and an electron injection layer EIL, but embodiments of the disclosure are not limited thereto.

The hole injection layer HIL can inject holes from the pixel electrode PE to the hole transport layer HTL, and the hole transport layer HTL can transport holes to the light emitting layer EML. The electron injection layer EIL can inject electrons from the common electrode CE to the electron transport layer ETL, and the electron transport layer ETL can transport electrons to the light emitting layer EML.

For example, the common electrode CE can be electrically connected to the base voltage line VSSL. A base voltage VSS, which is a type of common driving signal, can be applied to the common electrode CE through the base voltage line VSSL. The pixel electrode PE can be electrically connected directly or indirectly (through another transistor) to the first node Na of the driving transistor DT of each subpixel SP. In the disclosure, “base voltage VSS” can also be referred to as a “low-potential power voltage” or a “low-potential voltage,” and “base voltage line VSSL” can also be referred to as a “low-potential power voltage line” or a “low-potential voltage line.”

Each light emitting element ED can include an overlapping portion of the pixel electrode PE, the light emitting layer EML in the light emitting unit EL, and the common electrode CE. A predetermined light emitting area (i.e., emission area) can be formed by each light emitting element ED. For example, the light emitting area of each light emitting element ED can include an overlapping area of the pixel electrode PE, the light emitting layer EML in the light emitting unit EL, and the common electrode CE.

For example, the light emitting element ED can be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the light emitting unit EL of the light emitting element ED can include a light emitting unit EL including an organic material.

The driving transistor DT can be a driving transistor for supplying a driving current to the light emitting element ED. The driving transistor DT can be connected between a driving voltage line VDDL and the light emitting element ED.

The driving transistor DT can include a first node Na, a second node Nb, and a third node Nc. The first node Na can be electrically connected to the light emitting element ED, the second node Nb can receive a data signal VDATA, and the third node Nc can receive a driving voltage VDD from the driving voltage line VDDL. The driving transistor DT can be connected to the first node Na and the third node Nc.

In the driving transistor DT, the second node Nb can be a gate node, the first node Na can be a source node or a drain node, and the third node Nc can be a drain node or a source node. Hereinafter, for convenience of description, an example is described in which in the driving transistor DT, the second node Nb can be a gate node, the first node Na can be a source node, and the third node Nc can be a drain node, but embodiments of the disclosure are not limited thereto.

The scanning transistor ST included in the subpixel circuit SPC illustrated in FIG. 2 can be a switching transistor for transferring the data signal VDATA, which is an image signal, to the second node Nb, which is the gate node of the driving transistor DT.

The scanning transistor ST can be controlled to be turned on and off by the scan signal SC, which is a gate signal applied through the scan line SCL, which is a type of the gate line GL, to control electrical connection between the second node Nb of the driving transistor DT and the data line DL. The drain electrode or the source electrode of the scanning transistor ST can be electrically connected to the data line DL, the source electrode or the drain electrode of the scanning transistor ST can be electrically connected to the second node Nb of the driving transistor DT, and the gate electrode of the scanning transistor ST can be electrically connected to the scan line SCL.

The storage capacitor Cst can be electrically connected between the first node Na and second node Nb of the driving transistor DT. The storage capacitor Cst can include a first capacitor electrode electrically connected to the first node Na of the driving transistor DT or corresponding to the first node Na of the driving transistor DT, and a second capacitor electrode electrically connected to the second node Nb of the driving transistor DT or corresponding to the second node Nb of the driving transistor DT.

The storage capacitor Cst can be an external capacitor intentionally designed to be outside the driving transistor DT, but not a parasite capacitor (e.g., gate-source capacitor Cgs or gate-drain capacitor Cgd) which is an internal capacitor that can be present between the first node Na and the second node Nb of the driving transistor DT, but embodiments of the disclosure are not limited thereto.

Each of the driving transistor DT and the scanning transistor ST can be an n-type transistor or a p-type transistor, but embodiments of the disclosure are not limited thereto. For example, one of the driving transistor DT and the scanning transistor ST can be either an n-type transistor or a p-type transistor.

The display panel 110 can have a top emission structure or a bottom emission structure.

When the display panel 110 has a top emission structure, at least a portion of the subpixel circuit SPC can overlap at least a portion of the light emitting element ED in a vertical direction. Accordingly, the area of the emission area can increase and the aperture ratio can increase.

When the display panel 110 has a bottom emission structure, the subpixel circuit SPC may not overlap the light emitting element ED in the vertical direction.

As illustrated in FIG. 2, the subpixel circuit SPC can have a 2T (Transistor) 1C (Capacitor) structure including two transistors (i.e., driving transistor DT and scanning transistor ST) and one capacitor (i.e., storage capacitor Cst). In some cases, the subpixel circuit SPC can further include one or more transistors or can further include one or more capacitors.

For example, the subpixel circuit SPC can have an 8T1C structure including 8 transistors and 1 capacitor. As another example, the subpixel circuit SPC can have a 6T2C structure including 6 transistors and 2 capacitors. As another example, the subpixel circuit SPC can have a 7TIC structure including 7 transistors and 1 capacitor. However, embodiments of the disclosure are not limited thereto.

Depending on the structure of the subpixel circuit SPC, the type and number of gate lines or the gate signals supplied to the subpixel SP can vary. Further, the type and the number of common driving signals supplied to the subpixel SP can vary depending on the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 can be disposed in the display panel 110. The encapsulation layer 200 can prevent external moisture or oxygen from penetrating into circuit elements (e.g., the light emitting element ED). The encapsulation layer 200 can be configured in various forms so that the light emitting elements ED do not contact moisture or oxygen. For example, the encapsulation layer 200 can be constituted of two or more layers in which organic films and inorganic films are alternately stacked, but embodiments of the disclosure are not limited thereto.

Referring to FIG. 2, a display device 100 according to embodiments of the disclosure can include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 can be embedded in the display panel 110. For example, the touch sensor layer 210 can be disposed on the encapsulation layer 200 in the display panel 110. The touch sensor layer 210 can be a touch unit.

The display panel 110 can further include a plurality of touch pads TP electrically connected to the touch driving circuit 220 and a plurality of touch lines TL for electrically connecting the plurality of sensor electrodes included in the touch sensor layer 210 to the plurality of touch pads TP connected to the touch driving circuit 220.

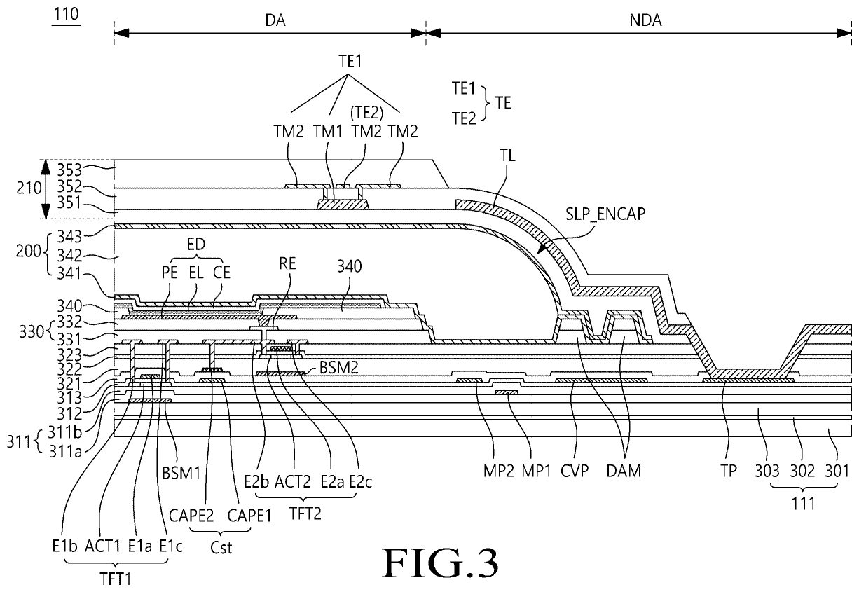

FIG. 3 is a partial cross-sectional view of a display panel 110 according to embodiments of the disclosure.

Referring to FIG. 3, the display panel 110 according to embodiments of the disclosure can include a transistor unit, a light emitting element portion, and an encapsulation portion, but embodiments of the disclosure are not limited thereto.

The substrate 111 can be a single layer or multiple layers. When the substrate 111 includes multiple layers, the substrate 111 can include a first substrate 301, an intermediate substrate layer (or intermediate layer) 302, and a second substrate 303. The intermediate substrate layer 302 can be positioned between the first substrate 301 and the second substrate 303. For example, each of the first substrate 301 and the second substrate 303 can be a polyimide (PI) layer, but embodiments of the disclosure are not limited thereto. The intermediate substrate layer 302 can be an inorganic insulation layer, but embodiments of the disclosure are not limited thereto. When an electric charge is charged to the first substrate 301 which is a polyimide layer, the intermediate substrate layer 302 can prevent the electric charge from affecting transistors disposed on the second substrate 303 through the second substrate 303 which is a polyimide layer.

Further, the intermediate substrate layer 302 can prevent a moisture component from penetrating upward through the first substrate 301. For example, the intermediate substrate layer 302 can be formed of a single layer of silicon nitride (SiNx) or silicon oxide (SiOx) or multiple layers thereof, or can be formed of a double layer of silicon dioxide (SiO₂) and silicon nitride (SiNx), but is not limited thereto.

The intermediate substrate layer 302 can be formed on the front surface of the substrate 111, but is not limited thereto. For example, the intermediate substrate layer 302 may not be formed in a portion of the non-display area NDA. Specifically, the intermediate substrate layer 302 including an inorganic material may not be formed in a place where stress is concentrated or cracks are likely to occur.

The transistor unit can include a substrate 111, buffer and insulation layers on the substrate 111, thin film transistors, a storage capacitor Cst, and various electrodes or signal lines.

The thin film transistors included in the transistor unit can include a first thin film transistor TFT1 and a second thin film transistor TFT2.

The first thin film transistor TFT1 can include a first active layer ACT1, a first electrode Ela, a second electrode E1b, and a third electrode E1c.

The first electrode Ela can be a gate electrode, the second electrode E1b can be a source electrode or a drain electrode, and the third electrode E1c can be a drain electrode or a source electrode. Hereinafter, for convenience of description, the first electrode Ela is referred to as a first gate electrode Ela, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The first active layer ACT1 can be a first semiconductor material, but embodiments of the disclosure are not limited thereto. For example, the first semiconductor material can include an oxide semiconductor, amorphous silicon, polysilicon, or low temperature polysilicon (LTPS), but embodiments of the disclosure are not limited thereto. The first thin film transistor TFT1 can be implemented as a p-channel thin film transistor or an n-channel thin film transistor, but embodiments of the disclosure are not limited thereto.

The second thin film transistor TFT2 can include a second active layer ACT2, a fourth electrode E2a, a fifth electrode E2b, and a sixth electrode E2c.

The fourth electrode E2a can be a gate electrode, the fifth electrode E2b can be a source electrode or a drain electrode, and the sixth electrode E2c can be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 can be a second semiconductor material, but embodiments of the disclosure are not limited thereto. For example, the second semiconductor material can include an oxide semiconductor, amorphous silicon, polysilicon, or low temperature polysilicon (LTPS), but embodiments of the disclosure are not limited thereto. The second thin film transistor TFT2 can be implemented as a p-channel thin film transistor or an n-channel thin film transistor, but embodiments of the disclosure are not limited thereto.

For example, one of the first active layer ACT1 of the first thin film transistor TFT1 and the second active layer ACT2 of the second thin film transistor TFT2 can include an oxide semiconductor material. As another example, one of the first active layer ACT1 of the first thin film transistor TFT1 and the second active layer ACT2 of the second thin film transistor TFT2 can include a low-temperature polysilicon semiconductor material. As another example, the first active layer ACT1 of the first thin film transistor TFT1 and the second active layer ACT2 of the second thin film transistor TFT2 can include an oxide semiconductor material. As another example, the first active layer ACT1 of the first thin film transistor TFT1 and the second active layer ACT2 of the second thin film transistor TFT2 can include a low-temperature polysilicon semiconductor material. As another example, of the first thin film transistor TFT1 and the second thin film transistor TFT2, the first thin film transistor TFT1 can configure an oxide semiconductor as an active layer, and the second thin film transistor TFT2 can configure low-temperature polysilicon as an active layer. As another example, of the first thin film transistor TFT1 and the second thin film transistor TFT2, the first thin film transistor TFT1 can configure low-temperature polysilicon as an active layer, and the second thin film transistor TFT2 can configure an oxide semiconductor as an active layer. As another example, a transistor included in a gate driving circuit 130 of a gate in panel (GIP) type can configure an oxide semiconductor or low-temperature polysilicon as an active layer. As another example, all the transistors configured on the substrate 111 and transistors included in a gate driving circuit 130 of a gate in panel (GIP) type can configure an oxide semiconductor as an active layer.

The second active layer ACT2 of the second thin film transistor TFT2 can be positioned higher from the substrate 111 than the first active layer ACT1 of the first thin film transistor TFT1.

A first buffer layer 311 can be disposed under the first active layer ACT1 of the first thin film transistor TFT1, and a second buffer layer 321 can be disposed under the second active layer ACT2 of the second thin film transistor TFT2. For example, the first active layer ACT1 of the first thin film transistor TFT1 can be positioned on the first buffer layer 311, and the second active layer ACT2 of the second thin film transistor TFT2 can be positioned on the second buffer layer 321. The second buffer layer 321 can be positioned higher than the first buffer layer 311.

The storage capacitor Cst can be disposed in various metal layers in the display panel 110. For example, the storage capacitor Cst can include a first capacitor electrode CAPE1 and a second capacitor CAPE2.

The light emitting element portion can include a plurality of light emitting elements ED disposed on a planarization layer 330 which will be described in detail hereinafter. Each of the plurality of light emitting elements ED can include a pixel electrode PE, a light emitting unit EL, and a common electrode CE.

The encapsulation portion can include an encapsulation layer 200 on the plurality of light emitting elements ED. The encapsulation layer 200 can be a single layer or multiple layers, but embodiments of the disclosure are not limited thereto. The encapsulation portion can further include a dam DAM in addition to the encapsulation layer 200.

Hereinafter, a structure or a vertical structure of the display panel 110 according to embodiments of the disclosure is described in more detail with reference to FIG. 3.

Referring to FIG. 3, the first buffer layer 311 can be disposed on the substrate 111. The first buffer layer 311 can be a single layer or multiple layers, but embodiments of the disclosure are not limited thereto. When the first buffer layer 311 includes multiple layers, the first buffer layer 311 can include a lower buffer layer 311a and an upper buffer layer 311b.

The first active layer ACT1 of the first thin film transistor TFT1 can be disposed on the first buffer layer 311. The first active layer ACT1 can include a channel area in which a channel is formed, a source connection area on one side of the channel area, and a drain connection area on the other side of the channel area.

A first insulation layer 312 can be disposed on the first active layer ACT1 of the first thin film transistor TFT1. The first gate electrode Ela of the first thin film transistor TFT1 can be disposed on the first insulation layer 312. A second insulation layer 313 can be disposed on the first gate electrode Ela of the first thin film transistor TFT1. The first insulation layer 312 can be a gate insulation layer, but embodiments of the disclosure are not limited thereto. The second insulation layer 313 can be an interlayer insulation layer, but embodiments of the disclosure are not limited thereto.

The second buffer layer 321 can be disposed on the second insulation layer 313.

The second active layer ACT2 of the second thin film transistor TFT2 can be disposed on the second buffer layer 321. The second active layer ACT2 can include a channel area in which a channel is formed, a source connection area on one side of the channel area, and a drain connection area on the other side of the channel area.

A third insulation layer 322 can be disposed on the second active layer ACT2 of the second thin film transistor TFT2. The second gate electrode E2a of the second thin film transistor TFT2 can be disposed on the third insulation layer 322. A fourth insulation layer 323 can be disposed on the second gate electrode E2a of the second thin film transistor TFT2. The third insulation layer 322 can be a gate insulation layer, but embodiments of the disclosure are not limited thereto. The fourth insulation layer 323 can be an interlayer insulation layer, but embodiments of the disclosure are not limited thereto.

The first source electrode E1b and the first drain electrode E1c of the first thin film transistor TFT1, and the second source electrode E2b and the second drain electrode E2c of the second thin film transistor TFT2 can be disposed on the fourth insulation layer 323.

The first source electrode E1b and the first drain electrode E1c of the first thin film transistor TFT1 can be connected to the source connection area and the drain connection area, respectively, of the first active layer ACT1 through holes of the fourth insulation layer 323, the third insulation layer 322, the second buffer layer 321, the second insulation layer 313, and the first insulation layer 312.

The second source electrode E2b and the second drain electrode E2c of the second thin film transistor TFT2 can be connected to the source connection area and the drain connection area, respectively, of the second active layer ACT2 through holes of the fourth insulation layer 323 and the third insulation layer 322.

The first source electrode E1b and the first drain electrode E1c of the first thin film transistor TFT1, and the second source electrode E2b and the second drain electrode E2c of the second thin film transistor TFT2 can include a first metal and can be disposed in the first metal layer. Here, the first metal and the first metal layer can be referred to as a first source-drain metal and a first source-drain metal layer.

For example, the storage capacitor Cst can be formed by a first capacitor electrode CAPE1 and a second capacitor electrode CAPE2. In some cases, the storage capacitor Cst can be formed by three or more capacitor electrodes, or can have a form in which two or more capacitors are connected in parallel.

Each of the first capacitor electrode CAPE1 and the second capacitor electrode CAPE2 can be disposed on various metal layers disposed in the display panel 110.

For example, the first capacitor electrode CAPE1 can include the same first gate metal as the first gate electrode Ela of the first thin film transistor TFT1 on the first insulation layer 312 and can be disposed in the first gate metal layer, but embodiments of the disclosure are not limited thereto. For example, the second capacitor electrode CAPE2 can be disposed on the second insulation layer 313.

The second source electrode E2b of the second thin film transistor TFT2 can be electrically connected to the second capacitor electrode CAPE2 through holes of the fourth insulation layer 323, the third insulation layer 322, and the second buffer layer 321.

For example, when the subpixel SP is configured as shown in FIG. 2, the first thin film transistor TFT1 can be the scanning transistor ST of FIG. 2, and the second thin film transistor TFT2 can be the driving transistor DT of FIG. 2.

The transistor unit can further include a first additional metal layer MP1 and a second additional metal layer MP2. For example, the first additional metal layer MP1 can be disposed between the lower buffer layer 311a and the upper buffer layer 311b included in the first buffer layer 311, but embodiments of the disclosure are not limited thereto. The second additional metal layer MP2 can include the same first gate metal as the first gate electrode Ela of the first thin film transistor TFT1, and can be disposed in the first gate metal layer, but embodiments of the disclosure are not limited thereto. The first additional metal layer MP1 can be a first metal pattern, and the second additional metal layer MP2 can be a second metal pattern, but embodiments of the disclosure are not limited thereto.

Each of the first additional metal layer MP1 and the second additional metal layer MP2 can be disposed in the display area DA or the non-display area NDA.

The transistor unit can further include a first shield pattern BSM1 disposed on the substrate 111. The first shield pattern BSM1 can overlap the first active layer ACT1 of the first thin film transistor TFT1. The first shield pattern BSM1 can be disposed under the first active layer ACT1 of the first thin film transistor TFT1. For example, the first shield pattern BSM1 can be disposed between the substrate 111 and the first buffer layer 311, or can be disposed between the lower buffer layer 311a and the upper buffer layer 311b.

The transistor unit can further include a second shield pattern BSM2 disposed on the substrate 111. The second shield pattern BSM2 can overlap the second active layer ACT2 of the second thin film transistor TFT2. The second shield pattern BSM2 can be disposed under the second active layer ACT2 of the second thin film transistor TFT2. For example, the second shield pattern BSM2 can be disposed in a metal layer between the second insulation layer 313 and the second buffer layer 321. The second shield pattern BSM2 can be disposed in the same metal layer as the second capacitor electrode CAPE2, but embodiments of the disclosure are not limited thereto. As another example, the second shield pattern BSM2 can be disposed in the same first gate metal layer as the first gate electrode Ela of the first thin film transistor TFT1.

The transistor unit can further include a common driving signal layer CVP to which a common driving signal is applied. The common driving signal layer CVP can be disposed in the display area DA or the non-display area NDA.

For example, the common driving signal applied to a common driving signal layer CVP can also be referred to as a power signal and can include at least one of a driving voltage VDD and a base voltage VSS. The driving voltage VDD can be referred to as a high-potential driving voltage (a high-potential power supply voltage or a high-potential voltage), and the base voltage VSS can be referred to as a low-potential driving voltage (a low-potential power supply voltage or a low-potential voltage).

The planarization layer 330 can be disposed on the first thin film transistor TFT1 and the second thin film transistor TFT2, and can be disposed under the light emitting element ED. The planarization layer 330 can be an organic insulation layer including an organic insulating material.

For example, the planarization layer 330 can be constituted of one layer. As another example, the planarization layer 330 can include two layers. The planarization layer 330 can include a first planarization layer 331 and a second planarization layer 332. As another example, the planarization layer 330 can include three or more layers. However, embodiments of the disclosure are not limited thereto.

The first planarization layer 331 can be disposed on the first source electrode E1b and the first drain electrode E1c of the first thin film transistor TFT1, and the second source electrode E2b and the second drain electrode E2c of the second thin film transistor TFT2. For example, the first planarization layer 331 can be disposed on the first thin film transistor TFT1 and the second thin film transistor TFT2. For example, the first planarization layer 331 can be disposed while covering both the first thin film transistor TFT1 and the second thin film transistor TFT2.

A connection electrode RE can be disposed on the first planarization layer 331. The connection electrode RE can electrically connect the second source electrode E2b of the second thin film transistor TFT2 and the pixel electrode PE.

The connection electrode RE can be electrically connected to the second source electrode E2b of the second thin film transistor TFT2 through a hole of the first planarization layer 331. The second source electrode E2b of the second thin film transistor TFT2 can be electrically connected to the second capacitor electrode CAPE2 of the storage capacitor Cst.

The connection electrode RE can be disposed in the second metal layer on the first planarization layer 331 and can include a second metal. The second metal and the second metal layer can be referred to as a second source-drain metal and a second source-drain metal layer.

The second planarization layer 332 can be disposed on the connection electrode RE.

The light emitting element unit can be disposed on the second planarization layer 332. The light emitting element ED can be formed on the second planarization layer 332. The light emitting element ED can include a pixel electrode PE, a light emitting unit EL, and a common electrode CE. The emission area of the light emitting element ED can be formed in an area in which the pixel electrode PE, the light emitting unit EL, and the common electrode CE overlap and contact each other.

The pixel electrode PE can be disposed on the second planarization layer 332. The pixel electrode PE can be electrically connected to the connection electrode RE through a hole of the second planarization layer 332.

A bank 340 can be disposed on the pixel electrode PE. An opening of the bank 340 can expose a portion of the pixel electrode PE to form the emission area. The opening of the bank 340 can overlap a portion of the pixel electrode PE.

For example, the bank 340 can be formed of a material including a black pigment, or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, it can be a black bank. When the bank 340 is formed of a material including a black pigment or a black dye, light from the outside can be blocked or light reflected from the outside can be blocked, and thus the luminance of the display device 100 can be further enhanced.

The light emitting unit EL of the light emitting element ED can be disposed on a portion of the pixel electrode PE and the bank 340. The common electrode CE can be disposed on the light emitting unit EL.

The encapsulation portion can be disposed on the light emitting element unit and can be positioned on the common electrode CE. The encapsulation portion can include the encapsulation layer 200 formed on the common electrode CE.

The encapsulation layer 200 can prevent moisture or oxygen from penetrating into the light emitting element ED. For example, the encapsulation layer 200 can prevent moisture or oxygen from penetrating into the organic material included in the light emitting unit EL of the light emitting element ED. The encapsulation layer 200 can be formed of a single layer or multiple layers, but embodiments of the disclosure are not limited thereto.

For example, the encapsulation layer 200 can include a first encapsulation layer 341, a second encapsulation layer 342, and a third encapsulation layer 343, but embodiments of the disclosure are not limited thereto. For example, the first encapsulation layer 341 and the third encapsulation layer 343 can include an inorganic layer, and the second encapsulation layer 342 can include an organic layer, but embodiments of the disclosure are not limited thereto.

The display panel 110 according to embodiments of the disclosure can have a built-in touch sensor. In this case, the display panel 110 according to embodiments of the disclosure can include a touch sensor layer 210 formed on the encapsulation layer 200. The touch sensor layer 210 can be a touch unit.

The touch sensor layer 210 can include a plurality of touch electrodes TE corresponding to touch sensors, and can include a touch metal layer in which a plurality of touch metals are disposed to form a plurality of touch electrodes TE.

For example, the touch metal layer can include a first touch metal layer in which a plurality of first touch metals TM1 are disposed, and a second touch metal layer in which a plurality of second touch metals TM2 are disposed. In this case, the touch sensor layer 210 can include a touch insulation layer 352 between the first touch metal layer and the second touch metal layer.

One of the first touch metal layer and the second touch metal layer can be a sensor metal layer and the other can be a bridge metal layer.

For example, the first touch metal layer can be a bridge metal layer, and the second touch metal layer can be a sensor metal layer. In this case, the plurality of second touch metals TM2 disposed in the second touch metal layer can be sensor metals forming touch sensors, and the plurality of first touch metals TM1 disposed in the first touch metal layer can be bridge metals electrically connecting the plurality of second touch metals TM2, which are sensor metals.

As another example, the first touch metal layer can be a sensor metal layer, and the second touch metal layer can be a bridge metal layer. In this case, the plurality of first touch metals TM1 disposed in the first touch metal layer can be sensor metals forming touch sensors, and the plurality of second touch metals TM2 disposed in the second touch metal layer can be bridge metals electrically connecting the plurality of first touch metals TM1, which are sensor metals.

As another example, each of the first touch metal layer and the second touch metal layer can be a sensor metal layer and a bridge metal layer. For example, the first touch metal layer can be a sensor metal layer and a bridge metal layer, and the second touch metal layer can be a sensor metal layer and a bridge metal layer. In this case, the plurality of first touch metals TM1 disposed in the first touch metal layer can include sensor metals and bridge metals, and the plurality of second touch metals TM2 disposed in the second touch metal layer can include sensor metals and bridge metals.

The touch sensor layer 210 can include at least one insulation layer (or touch insulation layer).

For example, the touch sensor layer 210 can include a touch insulation layer 352 disposed between the first touch metal layer in which the plurality of first touch metals TM1 are disposed and the second touch metal layer in which the plurality of second touch metals TM2 are disposed. For example, the touch insulation layer 352 can be an inorganic layer including an inorganic insulating material or an organic layer including an organic insulating material.

As another example, the touch sensor layer 210 can further include a touch buffer layer 351 between the encapsulation layer 200 and the touch metal layer. The touch buffer layer 351 can be disposed between the encapsulation layer 200 and the first touch metal layer in which a plurality of first touch metals TM1 are disposed. Here, the touch buffer layer 351 can be omitted. For example, the touch buffer layer 351 can be an inorganic layer including an inorganic insulating material or an organic layer including an organic insulating material.

As another example, the touch sensor layer 210 can further include a touch protection layer 353 on the touch metal layer. The touch protection layer 353 can be disposed on the first touch metal layer in which a plurality of second touch metals TM2 are disposed. For example, the touch protection layer 353 can be an inorganic layer including an inorganic insulating material or an organic layer including an organic insulating material. The touch protection layer 353 can extend to an upper portion of the touch line TL. The touch protection layer 353 can further extend to an upper portion of the touch pad TP.

Each of the plurality of touch electrodes TE can be formed of at least one second touch metal TM2. Each of the plurality of touch electrodes TE can be a mesh type electrode having a plurality of openings, but embodiments of the disclosure are not limited thereto.

For example, the plurality of touch electrodes TE can include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor can be electrically connected through the first touch metals TM1, which are bridge metals. For example, the second touch metals TM2 spaced apart from each other can be electrically connected by the first touch metal TM1 to constitute one first touch electrode TE1.

The plurality of first touch metals TM1 can be disposed on the touch buffer layer 351. The touch insulation layer 352 can be disposed on the plurality of first touch metals TM1. The plurality of second touch metals TM2 can be disposed on the touch insulation layer 352. Some of the plurality of second touch metals TM2 can be connected to the corresponding first touch metal TM1 through a hole in the touch insulation layer 352.

Referring to FIG. 3, the plurality of first touch metals TM1 and the plurality of second touch metals TM2 can be disposed not to overlap the light emitting element ED. The plurality of first touch metals TM1 and the plurality of second touch metals TM2 can overlap the bank 340.

The touch protection layer 353 can be disposed on the touch metal layer. The touch protection layer 353 can be disposed while covering the plurality of first and second touch metals TM1 and TM2 disposed in the touch metal layer.

The touch line TL can electrically connect the touch electrode TE to the touch pad TP. The touch line TL can be formed of at least one of the first touch metal TM1 and the second touch metal TM2. For example, the touch line TL can be configured in at least one of the first touch metal layer and the second touch metal layer. However, embodiments of the disclosure are not limited thereto.

The touch line TL can be formed of a first touch metal TM1, the touch line TL can be formed of a second touch metal TM2 or formed of a first touch metal TM1 and a second touch metal TM2. When one touch line TL is formed of the first touch metal TM1 and the second touch metal TM2, the first touch metal TM1 and the second touch metal TM2 constituting one touch line TL can be electrically connected through the hole in the touch insulation layer 352.

When the display panel 110 is of a type in which a touch sensor is embedded, the touch line TL can extend along the outer inclined surface SLP_ENCAP of the encapsulation layer 200, and can extend beyond an upper portion of at least one dam DAM to the touch pad TP in the non-display area NDA.

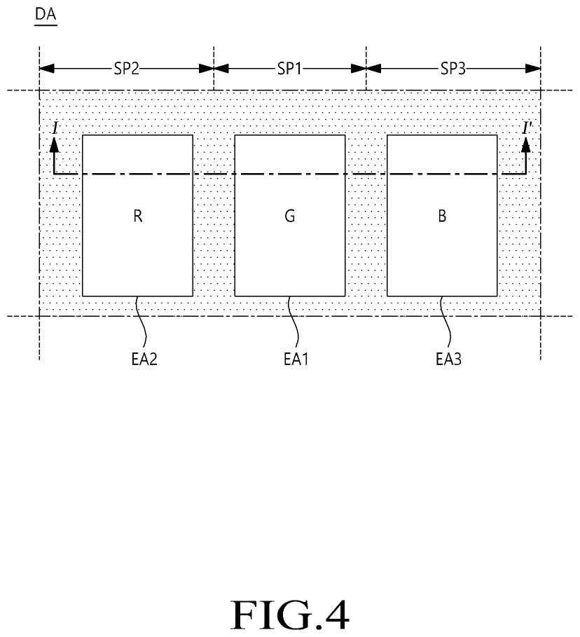

FIG. 4 illustrates a portion of a display area DA including a plurality of subpixels SP in a display panel 110 according to embodiments of the disclosure.

Referring to FIG. 4, a plurality of subpixels SP according to embodiments of the disclosure can include a first subpixel SP1, a second subpixel SP2, and a third subpixel SP3.

The first subpixel SP1, the second subpixel SP2, and the third subpixel SP3 can be disposed at regular intervals in the display area DA.

For example, by driving the transistor unit and the light emitting element portion of the display panel 110, the first subpixel SP1 can include a first emission area EA1 that emits green (G) light, the second subpixel SP2 can include a second emission area EA2 that emits red (R) light, and the third subpixel SP3 can include a third emission area EA3 that emits blue (B) light. However, embodiments of the disclosure are not limited thereto.

A light emitting element ED included in the first subpixel SP1 and emitting green (G) light can be disposed in the first emission area EA1. A light emitting element ED included in the second subpixel SP2 and emitting red (R) light can be disposed in the second emission area EA2. A light emitting element ED included in the third subpixel SP3 and emitting blue (B) light can be disposed in the third emission area EA3. In embodiments according to the disclosure, the first subpixel SP1, the second subpixel SP2, and the third subpixel SP3 are illustrated to have the same shape, but the disclosure is not limited thereto. For example, the first, second and third subpixels SP1, SP2, and SP3 can have a rhombus, a circular shape, or the like, and can have different sizes. Further, in embodiments according to the disclosure, the first subpixel SP1, the second subpixel SP2, and the third subpixel SP3 are illustrated to be disposed one by one in the first direction, but the disclosure is not limited thereto. For example, the first, second and third subpixels SP1, SP2, and SP3 can be disposed in a zigzag pattern. Further, the first subpixel SP1, the second subpixel SP2, and the third subpixel SP3 each can include a main light emitting element and a redundancy light emitting element. For example, a light emitting element ED that emits green (G) light can be disposed in the first subpixel SP1. The first subpixel SP1 can include a main light emitting element that emits green (G) light and a redundancy light emitting element that emits green (G) light.

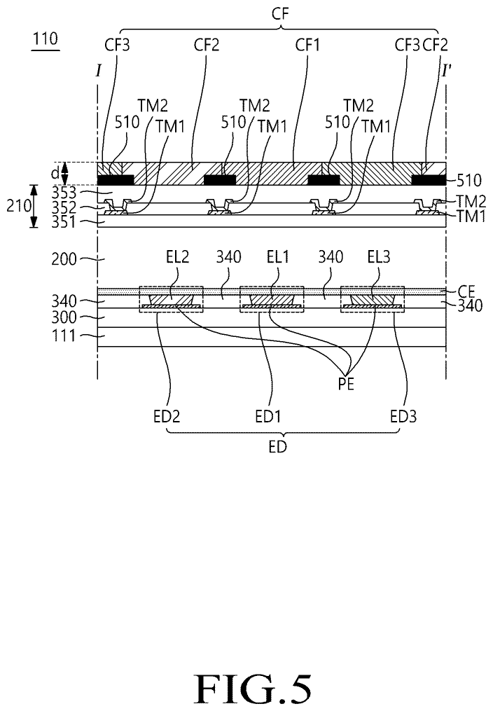

FIGS. 5 to 8 are cross-sectional views illustrating a plurality of subpixels SP taken along lie I-I′ of FIG. 4 in a display panel according to embodiments of the disclosure.

Particularly, FIG. 5 is a cross-sectional view illustrating the first subpixel SP1, the second subpixel SP2, and the third subpixel SP3 taken along line I-I′ of FIG. 4.

Referring to FIG. 5, the plurality of subpixels SP according to embodiments of the disclosure can include a substrate 111, a transistor unit 300, a plurality of light emitting elements ED, an encapsulation unit 200, a touch unit 210, a plurality of color filters CF, and a black matrix 510, and a duplicate description of the above-described components is omitted.

The plurality of color filters CF can include a first color filter CF1, a second color filter CF2, and a third color filter CF3. Light emitted from the first color filter CF1 can have a first wavelength, light emitted from the second color filter CF2 can have a second wavelength different from the first wavelength, and light emitted from the third color filter CF3 can have a third wavelength different from the first wavelength and the second wavelength.

Among the first wavelength, the second wavelength, and the third wavelength, the third wavelength can be the shortest, and the second wavelength can be the longest. The first wavelength can be green light, the second wavelength can be red light, and the third wavelength can be blue light, but the disclosure is not limited thereto. The first wavelength, the second wavelength, and the third wavelength can be peak wavelengths.

The light emitting unit EL included in the plurality of light emitting elements ED can include a first light emitting unit EL1 emitting first light, a second light emitting unit EL2 emitting second light, and a third light emitting unit EL3 emitting third light.

The first light can be green light, the second light can be red light, and the third light can be blue light, but the disclosure is not limited thereto.

Each of the plurality of subpixels SP can include a light emitting unit EL that emits different light and a color filter CF that emits light of a different wavelength, and each light emitting unit EL and the color filter CF are disposed to overlap each other.

For example, among a plurality of light emitting elements ED, the first light emitting unit EL1 included in the first light emitting element ED1 can overlap the first color filter CF1, the second light emitting unit EL2 included in the second light emitting element ED2 can overlap the second color filter CF2, and the third light emitting unit EL3 included in the third light emitting element ED3 can overlap the third color filter CF3.

The black matrix 510 is disposed to overlap the first touch metal TM1, and be disposed to overlap a boundary between the plurality of color filters CF to partition each of the plurality of color filters CF.

For example, the black matrix 510 can be formed of an organic insulating material, e.g., a colored organic resin such as acryl, epoxy, or polyimide resin, including any one of carbon black and black pigments, but the disclosure is not limited thereto.

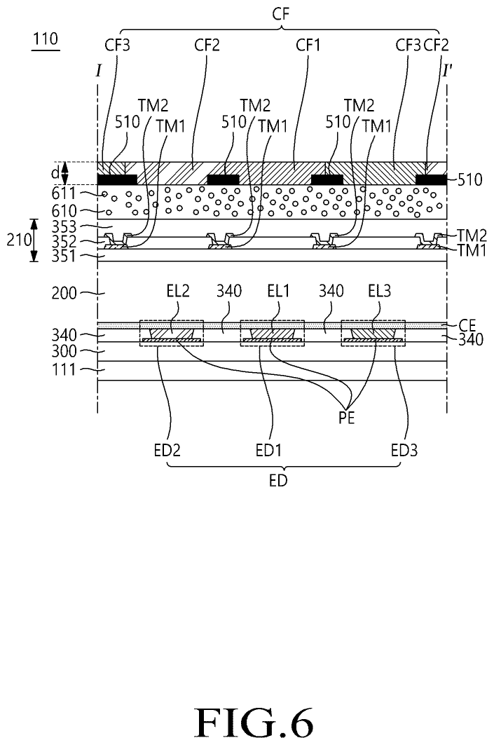

FIG. 6 is a cross-sectional view illustrating a plurality of subpixels SP including a light scattering layer 610 taken along line I-I′ of FIG. 4 in a display panel 110 according to embodiments of the disclosure.

Referring to FIG. 6, the light scattering layer 610 is disposed between the touch unit 210 and the color filter CF, and can include light scattering particles 611.

For example, the light scattering layer 610 can include light scattering particles 611 positioned corresponding to at least one of the plurality of color filters CF. For example, in the light scattering layer 610, the light scattering particle 611 can be positioned in an area overlapping the first color filter CF1 but may not be positioned in an area overlapping the second color filter CF2 and the third color filter CF3.

As another example, in the light scattering layer 610, the weight percent (unit: wt %) of the light scattering particles 611 can be different for each position. For example, in the light scattering layer 610, the weight percent of light scattering particles 611 positioned in the area overlapping the first color filter CF1 and the weight percent of light scattering particles 611 positioned in the area overlapping the second color filter CF2 and the third color filter CF3 can be different.

The weight percent is a type of method for expressing the content or concentration, and can represent the mass occupied by the target component among the total mass of an object as a percentage.

For example, the weight percent of the light scattering particles 611 included in the light scattering layer 610 in the display panel 110 according to embodiments of the disclosure can be a percentage of the light scattering particles 611 within the total mass of the light scattering layer 610.

The light scattering layer 610 can scatter light present in the display panel 110. As the light scattering layer 610 in the display panel 110 scatters light incident thereon, rainbow mura, which is a type of stain recognized in the display device 100, can be mitigated.

External light incident on the display device 100 can be reflected by a metal material disposed in the display panel 110. For example, metal materials with high reflectivity applied to thin film transistors TFT, light emitting elements ED, and various lines can reflect external light. The reflected external light diffracts or interferes with each other, and is emitted back to the outside, causing rainbow mura that is perceived as color spreading like a rainbow.

The light scattering particles 611 included in the light scattering layer 610 according to embodiments of the disclosure can scatter external light reflected from the inside of the display panel 110.

For example, the external light specular-reflected by the metal material disposed in the display panel 110 can collide with the light scattering particles 611 and be diffuse-reflected. Since the level of rainbow mura becomes stronger as the external light is specular-reflected, the light scattering layer 610 can cancel the reflected external light by diffuse-reflecting it.

As rainbow mura is mitigated, screen visibility of the display device 100 can be enhanced.

Hereinafter, a process of forming the light scattering layer 610 according to embodiments of the disclosure is briefly described.

After the process of forming the touch unit 210, the light scattering layer 610 is formed on the touch unit 210, and the process of forming the light scattering layer 610 can include a coating step, an exposure step, a development step, and a heat treatment step, but the disclosure is not limited thereto.

In the coating step, a mixture in which light scattering particles 611 are mixed with an organic solvent can be applied to the upper surface of the touch unit 210. For example, for the mixture of the light scattering layer 610, one of spin coating, slit coating, bar coating, roll coating, and inkjet coating can be used.

In the exposure step, the light scattering layer 610 can be cured by irradiating light such as UV to the mixture of the light scattering layer 610 applied in a solution state.

The developing step can be a step of removing or patterning a partial area of the cured light scattering layer 610 through a developer.

The heat treatment step can be a step of applying heat to more firmly fix the remaining light scattering layer 610 after going through the development step in the display panel 110.

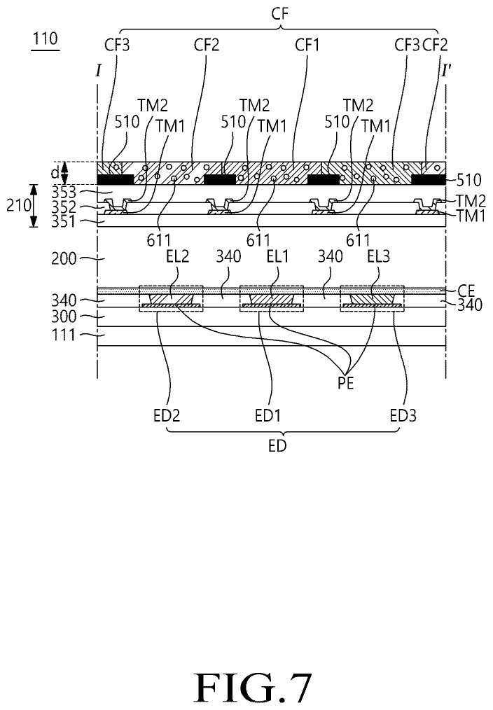

FIG. 7 is a cross-sectional view illustrating a plurality of subpixels SP in which light scattering particles 611 are included in a color filter CF taken along line I-I′ of FIG. 4 in a display panel 110 according to embodiments of the disclosure.

Referring to FIG. 7, two or more of the plurality of color filters CF can include light scattering particles 611.

According to embodiments of the disclosure, the light scattering particles 611 included in the plurality of color filters CF can scatter light present in the display panel 110. As the light scattering particles 611 scatter light incident thereon in the display panel 110, rainbow mura, a type of stain recognized by the display device 100, can be mitigated.

The light scattering particles 611 included in the plurality of color filters CF can scatter external light reflected from the inside of the display panel 110.

For example, the external light specular-reflected by the metal material disposed in the display panel 110 can collide with the light scattering particles 611 and be diffuse-reflected. Since the level of rainbow mura becomes stronger as the external light is specular-reflected, the light scattering layer 610 can cancel the reflected external light by diffuse-reflecting it.

As rainbow mura is mitigated, screen visibility of the display device 100 can be enhanced.

According to embodiments of the disclosure, as the light scattering particles 611 are included in the plurality of color filters CF, color mixing in the display panel 110 can be prevented.

Hereinafter, color mixing that can occur in the display panel 110 according to embodiments of the disclosure is described with reference to FIGS. 6 and 7.

Referring to FIG. 6, the light scattering layer 610 according to embodiments of the disclosure can be disposed under the plurality of color filters CF. The thickness occupied by the light scattering layer 610 in the display panel 110 can affect color mixing of at least one type of light emitted from the display panel 110 to the outside.

For example, the light scattering layer 610 can have a thickness of 3 to 5 μm.

The first light emitted from the first light emitting unit EL1 of the light emitting element ED, the second light emitted from the second light emitting unit EL2, and the third light emitted from the third light emitting unit EL3 can collide with the plurality of light scattering particles 611 included in the light scattering layer 610 and be thus scattered.

For example, the first light emitted in the upper direction of the display panel 110 is scattered, so that it can go straight in at least one or more directions. Therefore, the first light may not only pass through the light scattering layer 610 and enter the first color filter CF1, but can also enter the second color filter CF2 and the third color filter CF3 adjacent to the first color filter CF1.

Likewise, the second light can pass through the light scattering layer 610 and enter the second color filter CF2, as well as enter the first color filter CF1 adjacent to the second color filter CF2. The third light can pass through the light scattering layer 610 and enter the third color filter CF3 as well as enter the first color filter CF1 adjacent to the third color filter CF3.

As a result, the first light and the second light can overlap in the color filter CF, and the first light and the third light can overlap in the color filter CF, causing color mixing. The color-mixed light can pass through the color filter CF and exit the display panel 110, thereby deteriorating display quality.

Referring to FIG. 7, the plurality of color filters CF according to embodiments of the disclosure can include light scattering particles 611. In other words, as the light scattering layer 610 is removed and the plurality of color filters CF include light scattering particles 611, the function of the light scattering layer 610 can be applied to the color filter CF.

For example, the first light, the second light, and the third light can be scattered and emitted to the outside of the display panel 110 by colliding with the light scattering particles 611 included in the first color filter CF1, the second color filter CF2, and the third color filter CF3, respectively. Accordingly, the first light, the second light, and the third light are not mixed and can be emitted to the outside of the display panel 110.

According to embodiments of the disclosure, since the light scattering particles 611 are included in the plurality of color filters CF, the reliability of the light emitting element ED in the display panel 110 can be enhanced.

Since the light scattering particles 611 are included in the plurality of color filters CF, it is not necessary to form the above-described light scattering layer 610 through a separate process, and thus the reliability of the light emitting element ED can be enhanced by preventing damage to the materials of the first, second and third light emitting units EL1, EL2, and EL3.

Hereinafter, a process of forming a plurality of color filters CF including light scattering particles 611 according to embodiments of the disclosure is described with reference to FIGS. 6 and 7.

Referring to FIG. 7, after the process of forming the touch unit 210, the black matrix 510 can be patterned on the touch unit 210. A color filter CF including light scattering particles 611 is formed on the black matrix 510, and the process of forming the color filter CF can include a mixing step and a patterning step, but the disclosure is not limited thereto.

In the mixing step, light scattering particles 611 can be mixed with a color filter photoresist. The color filter photoresist can be a photosensitive material.

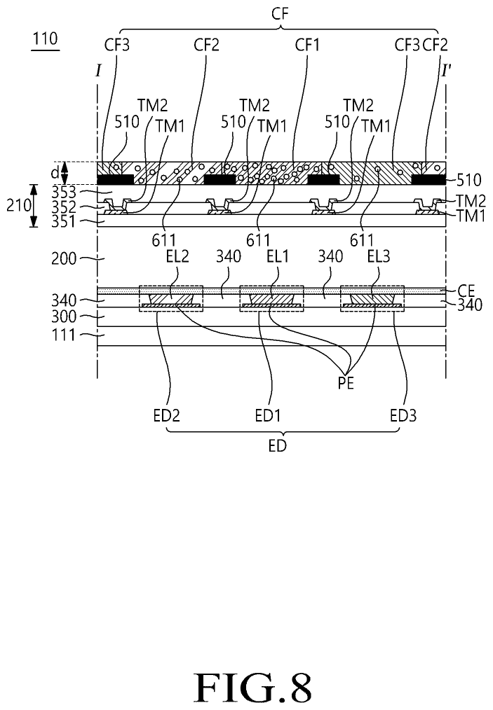

The light scattering particles 611 can be mixed with the first color filter CF1, second color filter CF2, and third color filter CF3 photoresist in different concentrations. The concentration of the light scattering particles 611 for each type of the color filter CF is described below with reference to FIG. 8.

In the patterning step, the first color filter CF1 is formed on the first subpixel SP1 by applying a mixture of the first color filter CF1 on the black matrix 510, drying it, and then exposing and developing it using a mask, and curing it. Subsequently, a second color filter CF2 and a third color filter CF3 are formed in the second subpixel SP2 and the third subpixel SP3, respectively, in the same manner. Accordingly, the plurality of color filters CF emitting light of a first wavelength, a second wavelength, and a third wavelength can be completed. The order of formation of the first color filter CF1, the second color filter CF2, and the third color filter CF3 is not limited thereto and can be changed.

Here, the first color filter CF1 mixture, the second color filter CF2 mixture, and the third color filter CF3 mixture can be applied by a coating method, and for example, one of spin coating, slit coating, bar coating, roll coating, and inkjet coating methods can be used. Further, the photosensitive color filter photoresist can be of a negative type in which a portion exposed to light remains after development. In contrast, the photosensitive color filter photoresist can be of a positive type in which a portion exposed to light is removed after development.

By mixing the light scattering particles 611 with the color filter photoresist, the light scattering layer 610 may not be formed.

Referring to FIG. 6, as described above, the process of forming the light scattering layer 610 can include a heat treatment step. When the heat treatment step is performed, the first light emitting unit EL1, the second light emitting unit EL2, and the third light emitting unit EL3 of the light emitting elements ED disposed under the light scattering layer 610 can be damaged.

For example, when the light emitting element ED is an organic light emitting diode (OLED), the first light emitting unit EL1, the second light emitting unit EL2, and the third light emitting unit EL3 can include an organic material. Since the organic material is vulnerable to heat, if the first, second and third light emitting units EL1, EL2, and EL3 go through a heat treatment process, the organic material included in the first, second and third light emitting units EL1, EL2, and EL3 can be damaged or inherent light emitting characteristics can be deteriorated.

Since the light scattering layer 610 does not need to be formed through a separate process, a heat treatment step is not required, and thus the reliability of the light emitting element ED can be enhanced by preventing damage to the organic materials of the first, second and third light emitting units EL1, EL2, and EL3.

FIG. 8 is a cross-sectional view illustrating a plurality of subpixels SP in which light scattering particles 611 are included in a color filter CF taken along line I-I′ of FIG. 4 in a display panel 110 according to embodiments of the disclosure.

Referring to FIG. 8, in the display panel 110 according to embodiments of the disclosure, a weight percent of the light scattering particles 611 included in one of the two or more color filters CF can be equal to or larger than a weight percent of the light scattering particles 611 included in the other color filters CF.

Hereinafter, a difference in the weight percent of the light scattering particles 611 for each type of the color filter CF is described.

The weight percent is a type of method for expressing the content or concentration, and can represent the mass occupied by the target component among the total mass of an object as a percentage.

For example, the weight percent of the light scattering particles 611 included in the first color filter CF1 in the display panel 110 according to embodiments of the disclosure can be a percentage of the light scattering particles 611 within the total mass of the first color filter CF1.

In the display panel 110 according to embodiments of the disclosure, the weight percent of the light scattering particles 611 included in the first to third color filters CF1 to CF3 can be a value set according to a predetermined level for rainbow mura recognized in the display device 100. For example, if rainbow mura is strong, the weight percent of the light scattering particles 611 can be set to a high value.

As the weight percent of the light scattering particles 611 included in the color filter CF increases, the degree to which light emitted from the light emitting element ED is scattered while passing through the color filter CF (hereinafter, referred to as a “light scattering degree”) can increase. When the light scattering degree increases, the light transmittance of the display panel 110 can decrease, and thus the light emission efficiency of the display panel 110 can decrease.

Therefore, in the display panel 110 according to embodiments of the disclosure, the color filter CF can be designed so that the weight percent of the light scattering particles 611 varies for each type of color filter CF considering both the level of rainbow mura and the light transmittance of the display panel 110.

The color filter CF emitting light of different wavelengths can also have different light transmission efficiency. The light transmission efficiency can be high in the order of green, red, and blue. In other words, the light transmission efficiency of the first color filter CF1 emitting the first wavelength can be higher than that of the second color filter CF2 emitting the second wavelength and the third color filter CF3 emitting the third wavelength. The light transmission efficiency of the second color filter CF2 emitting the second wavelength can be higher than that of the third color filter CF3 emitting the third wavelength.

In order to decrease the level of rainbow mura, for the color filter CF having the higher light transmission efficiency, the weight percent of the light scattering particles 611 can be increased.

In order not to decrease the light transmittance of a specific color in the display device 100, for the color filter having lower light transmission efficiency, the weight percent of the light scattering particles 611 can be decreased.

In the display panel according to embodiments of the disclosure, the weight percent of the light scattering particles 611 included in the first color filter CF1 can be larger than or equal to the weight percent of the light scattering particles 611 included in the second color filter CF2, and the weight percent of the light scattering particles 611 included in the second color filter CF2 can be larger than or equal to the weight percent of the light scattering particles 611 included in the third color filter CF3.

For example, the weight percent of the light scattering particles 611 included in the first color filter CF1 can be 0.1 to 0.2 wt %, the weight percent of the light scattering particles 611 included in the second color filter CF2 can be 0.05 to 0.1 wt %, and the weight percent of the light scattering particles 611 included in the third color filter CF3 can be 0.01 wt % or less.

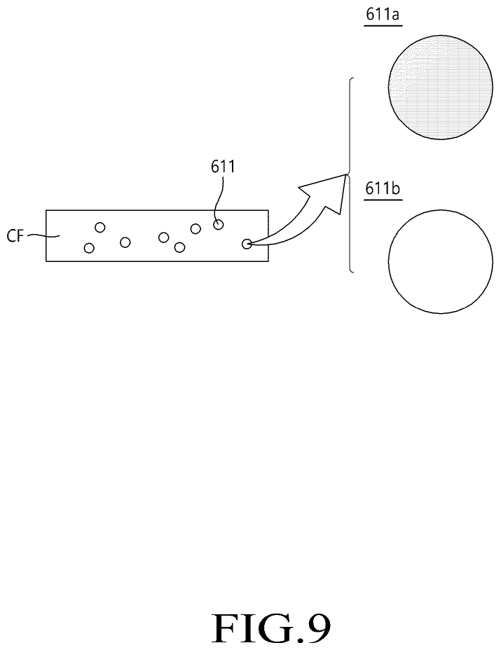

In this case, the light scattering particles 611 can be inorganic scattering particles 611a including an inorganic material, which is described below with reference to FIG. 9.

For example, the weight percent of the light scattering particles 611 included in the first color filter CF1 can be 0.5 wt % to 0.8 wt %, the weight percent of the light scattering particles 611 included in the second color filter CF2 can be 0.3 wt % to 0.5 wt %, and the weight percent of the light scattering particles 611 included in the third color filter CF3 can be 0.3 wt % or less.

In this case, the light scattering particles 611 can be organic scattering particles 611b including an organic material, which is described below with reference to FIG. 9.

For example, the weight percent of the light scattering particles 611 included in the first color filter CF1 can be 0.1 to 0.2 wt %, the weight percent of the light scattering particles 611 included in the second color filter CF2 can be 0.05 to 0.1 wt %, and the weight percent of the light scattering particles 611 included in the third color filter CF3 can be 0.01 wt % or less.

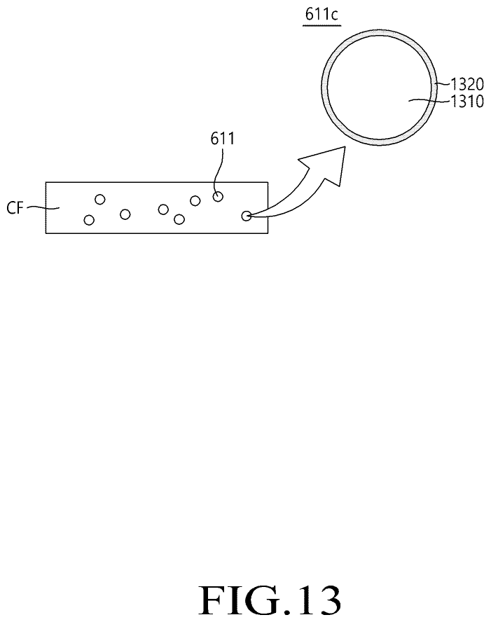

In this case, the light scattering particle 611 can be a hybrid-type scattering particle 611c, which is described below with reference to FIG. 13.

Referring to FIG. 8, the weight percent of the light scattering particles 611 included in the first color filter CF1 overlapping the first light emitting unit EL1 in the display panel 110 according to embodiments of the disclosure can be larger than or equal to the weight percent of the light scattering particles 611 included in the second color filter CF2 overlapping the second light emitting unit EL2.

The display panel 110 according to embodiments of the disclosure can include an encapsulation unit 200 overlapping two or more color filters having different weight percents of the light scattering particles 611.

In other words, the encapsulation unit 200 can be disposed to overlap two or more of the first color filter CF1, the second color filter CF2, and the third color filter CF3 having different weight percents of the light scattering particles 611.

In the display panel 110 according to embodiments of the disclosure, a first touch metal TM1 can overlap a boundary between two or more color filters having different weight percents of the light scattering particles 611.

In other words, the first touch metal TM1 can be disposed to overlap a boundary between the first color filter CF1 and the second color filter CF2, a boundary between the first color filter CF1 and the third color filter CF3, and a boundary between the second color filter CF2 and the third color filter CF3 adjacent to each other.

The display panel 110 according to embodiments of the disclosure can further include a black matrix 510 disposed on the touch unit 210, disposed to overlap the first touch metal TM1, and disposed in a boundary between two or more color filters CF having different weight percents of the light scattering particles 611.

In other words, the black matrix 510 can be disposed in a boundary between the first color filter CF1 and the second color filter CF2, a boundary between the first color filter CF1 and the third color filter CF3, and a boundary between the second color filter CF2 and the third color filter CF3 adjacent to each other.

The display panel 110 according to embodiments of the disclosure can further include a bank 340 disposed between a plurality of light emitting units EL and overlapping a boundary between two or more color filters CF having different weight percents of the light scattering particles 611.

In other words, the bank 340 can be disposed to overlap a boundary between the first color filter CF1 and the second color filter CF2, a boundary between the first color filter CF1 and the third color filter CF3, and a boundary between the second color filter CF2 and the third color filter CF3 adjacent to each other.

FIG. 9 illustrates a type of light scattering particles 611 included in a display panel 110 according to embodiments of the disclosure.

Referring to FIG. 9, the light scattering particles 611 included in the display panel 110 according to embodiments of the disclosure can include at least one of an inorganic material and an organic material.

For example, the light scattering particle 611 can be an inorganic scattering particle 611a including an inorganic material. The inorganic material can be TiO₂ and silica, but the disclosure is not limited thereto.

For example, the light scattering particle 611 can be an organic scattering particle 611b including an organic material. The organic material can be a polymer, but the disclosure is not limited thereto.

In the display panel 110 according to embodiments of the disclosure, the light scattering degree of the inorganic scattering particles 611a can be higher than the light scattering degree of the organic scattering particles 611b. Thus, the weight percent of the light scattering particles 611 included in the color filter CF when the light scattering particle 611 is an inorganic scattering particle 611a can be smaller than the weight percent of the light scattering particles 611 included in the color filter CF when the light scattering particle 611 is an organic scattering particle 611b.

For example, the weight percent of the light scattering particles 611 included in the color filter CF when the light scattering particle 611 is an inorganic scattering particle 611a can range from 0.01 to 0.2 wt %, and the weight percent of the light scattering particles 611 included in the color filter CF when the light scattering particle 611 is an organic scattering particle 611b can range from 0.3 to 0.8 wt %.

In the display panel 110 according to embodiments of the disclosure, the size of the organic scattering particle 611b can be smaller than the size of the inorganic scattering particle 611a. As the size of the light scattering particles 611 included in the color filter CF decreases, the thickness d of the color filter CF can decrease. The organic scattering particles 611b, although being smaller in size than the inorganic scattering particles 611a, can have a larger weight percent range in the color filter CF than the inorganic scattering particles 611a due to the low light scattering degree. Accordingly, the thickness d of the color filter CF including the organic scattering particles 611b can be larger than the thickness d of the color filter CF including the inorganic scattering particles 611a.

For example, referring to FIG. 8, when the light scattering particle 611 is an inorganic scattering particle 611a, the thickness d of the first color filter CF1 to the third color filter CF3 can be 3.0 to 4.0 μm, and when the light scattering particle 611 is an organic scattering particle 611b, the thickness d of the first color filter CF1 to the third color filter CF3 can be 4.0 to 5.0 μm.

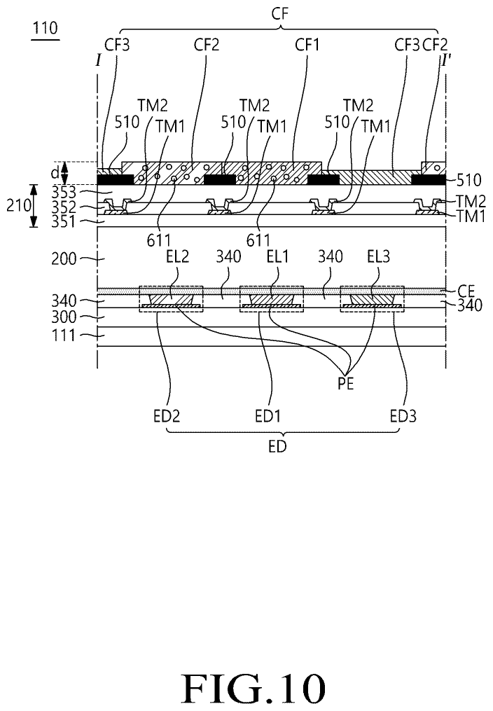

FIGS. 10 to 12 are cross-sectional views illustrating a plurality of subpixels SP taken along line I-I′ of FIG. 4 in a display panel 110 according to embodiments of the disclosure.

In the display panel 110 according to embodiments of the disclosure, the thickness d of each of the plurality of color filters CF can vary depending on whether the light scattering particles 611 are included or the weight percent (concentration) of the light scattering particles 611.

FIG. 10 illustrates a change in thickness d depending on whether the color filter CF includes the light scattering particles 611 in the display panel 110 according to embodiments of the disclosure.

In the display panel 110 according to embodiments of the disclosure, two or more color filters CF among the plurality of color filters CF can include light scattering particles 611. The thickness d of the color filter CF including the light scattering particles 611 can be larger than the thickness d of the color filter CF not including the light scattering particles 611.

Referring to FIG. 10, light scattering particles 611 can be included in the first color filter CF1 and the second color filter CF2 among the first to third color filters CF1 to CF3. The thickness d of the first color filter CF1 and the second color filter CF2 can be larger than the thickness d of the third color filter CF3 which does not include the light scattering particles 611.

For example, when the light scattering particle 611 is an inorganic scattering particle 611a, the thickness d of the first color filter CF1 and the second color filter CF2 including the light scattering particles 611 can be 3.0 to 4.0 μm, and the thickness d of the third color filter CF3 not including the light scattering particles 611 can be 2.0 to 3.0 μm.

For example, when the light scattering particle 611 is an organic scattering particle 611b, the thickness d of the first color filter CF1 and the second color filter CF2 including the light scattering particles 611 can be 4.0 to 5.0 μm, and the thickness d of the third color filter CF3 not including the light scattering particles 611 can be 3.0 to 4.0 μm.

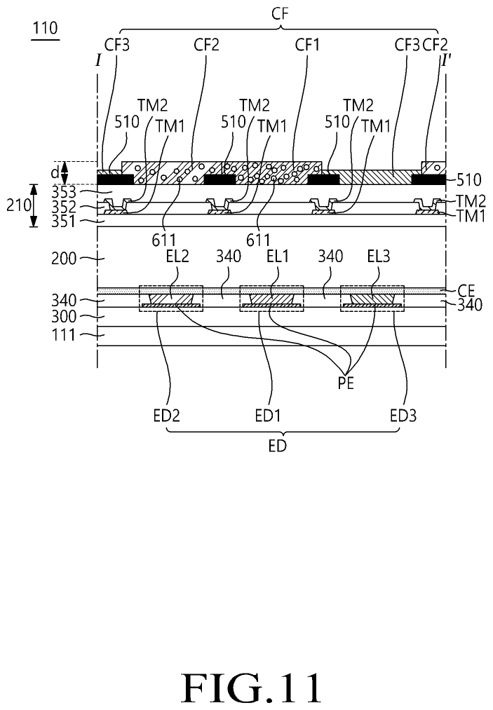

FIG. 11 illustrates a change in thickness d depending on whether the color filter CF includes the light scattering particles 611 in the display panel 110 according to embodiments of the disclosure and a difference in the weight percent of the light scattering particles 611 for each type of the color filter CF.

In the display panel 110 according to embodiments of the disclosure, two or more color filters CF among the plurality of color filters CF can include light scattering particles 611. The thickness d of the color filter CF including the light scattering particles 611 can be larger than the thickness d of the color filter CF not including the light scattering particles 611.

Referring to FIG. 11, the thickness d of the first color filter CF1 and the second color filter CF2 including the light scattering particles 611 can be larger than the thickness d of the third color filter CF3 not including the light scattering particles 611.

The weight percent of the light scattering particles 611 included in the first color filter CF1 can be larger than or equal to a weight percent of the light scattering particles 611 included in the second color filter CF2.

For example, when the light scattering particle 611 is an inorganic scattering particle 611a, the thickness d of the first color filter CF1 including the light scattering particles 611 can be 3.0 to 4.0 μm, and the weight percent of the light scattering particles 611 in the first color filter CF1 can be 0.1 to 0.2 wt %. The thickness d of the second color filter CF2 including the light scattering particles 611 can be 3.0 to 4.0 μm, and the weight percent of the light scattering particles 611 in the second color filter CF2 can be 0.05 to 0.1 wt %. The thickness d of the third color filter CF3 not including the light scattering particles 611 can be 2.0 to 3.0 μm.

For example, when the light scattering particle 611 is an organic scattering particle 611b, the thickness d of the first color filter CF1 including the light scattering particles 611 can be 4.0 to 5.0 μm, and the weight percent of the light scattering particles 611 in the first color filter CF1 can be 0.5 to 0.8 wt %. The thickness d of the second color filter CF2 including the light scattering particles 611 can be 4.0 to 5.0 μm, and the weight percent of the light scattering particles 611 in the second color filter CF2 can be 0.3 to 0.5 wt %. The thickness d of the third color filter CF3 not including the light scattering particles 611 can be 3.0 to 4.0 μm.

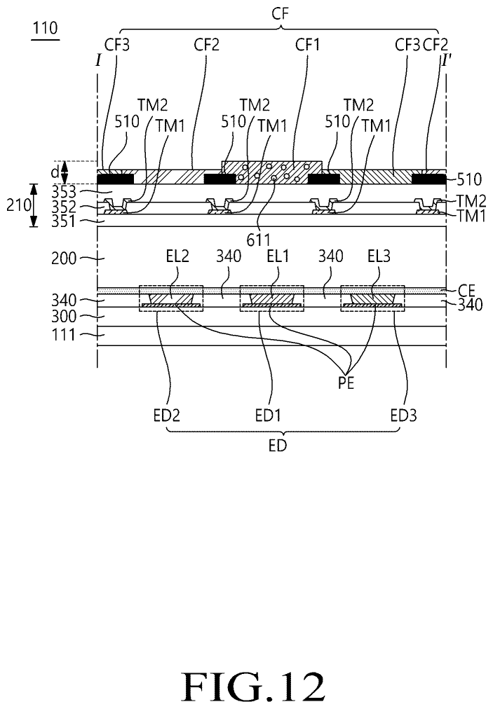

FIG. 12 illustrates a change in thickness d depending on whether the color filter CF includes the light scattering particles 611 in the display panel 110 according to embodiments of the disclosure.

At least one of the plurality of color filters CF in the display panel 110 according to embodiments of the disclosure can include light scattering particles 611. The thickness d of the color filter CF including the light scattering particles 611 can be larger than the thickness d of the color filter CF not including the light scattering particles 611.

Referring to FIG. 12, the light scattering particles 611 can be included in the first color filter CF1 among the first to third color filters CF1 to CF3. The thickness d of the first color filter CF1 can be larger than the thickness d of the second color filter CF2 and the third color filter CF3, which do not include the light scattering particles 611.

For example, when the light scattering particle 611 is an inorganic scattering particle 611a, the thickness d of the first color filter CF1 including the light scattering particles 611 can be 3.0 to 4.0 μm, and the thickness d of the second color filter CF2 and the third color filter CF3 not including the light scattering particles 611 can be 2.0 to 3.0 μm.

The weight percent of the inorganic scattering particles 611a included in the first color filter CF1 can be 0.1 to 0.2 wt %.

For example, when the light scattering particle 611 is an organic scattering particle 611b, the thickness d of the first color filter CF1 including the light scattering particles 611 can be 4.0 to 5.0 μm, and the thickness d of the second color filter CF2 and the third color filter CF3 not including the light scattering particles 611 can be 3.0 to 4.0 μm.

The weight percent of the organic scattering particles 611b included in the first color filter CF1 can be 0.5 to 0.8 wt %.

FIG. 13 illustrates a type of light scattering particles 611 included in a display panel 110 according to embodiments of the disclosure.

In the display panel 110 according to embodiments of the disclosure, the light scattering particles 611 can include an organic material and can further include an inorganic material.

Particularly, FIG. 13 illustrates a case in which the light scattering particles 611 included in the display panel 110 according to embodiments of the disclosure include both an inorganic material and an organic material.

Referring to FIG. 13, when the light scattering particle 611 includes both an inorganic material and an organic material, the light scattering particle 611 can have a core-shell structure including a shell 1320 including an inorganic material and a core 1310 including an organic material. Hereinafter, the light scattering particle 611 having a core-shell structure including both an inorganic material and an organic material is referred to as a “hybrid-type scattering particle 611c”.

The inorganic material forming the shell 1320 can be the same as the inorganic material applied to the inorganic scattering particle 611a. In other words, the inorganic material forming the shell 1320 can be TiO₂ and silica, but the disclosure is not limited thereto.

The organic material forming the core 1310 can be the same as the organic material applied to the organic scattering particle 611b. In other words, the organic material forming the core 1310 can be a polymer, but the disclosure is not limited thereto.

In the hybrid-type scattering particle 611c, the weight percent of the inorganic material can be smaller than or equal to the weight percent of the organic material. In other words, the weight of the shell 1320 in the hybrid-type scattering particle 611c can be smaller than or equal to the weight of the core 1310.

In the display panel 110 according to embodiments of the disclosure described above, the light scattering degree of the inorganic scattering particles 611a can be higher than that of the organic scattering particles 611b. Further, the size of the organic scattering particle 611b can be smaller than the size of the inorganic scattering particle 611a.

The hybrid-type scattering particle 611c can have both characteristics of the inorganic scattering particle 611a including an inorganic material and characteristics of the organic scattering particle 611b including an organic material. For example, the inorganic scattering particles 611a can have high light scattering characteristics. The organic scattering particles 611b can have a small particle size, and the organic scattering particles 611b can also have characteristics of increasing transmittance of the color filter CF including the organic scattering particles 611b. Thus, the hybrid-type scattering particle 611c can have both high light scattering characteristics and high transmittance characteristics.

For example, the weight percent of the hybrid-type scattering particles 611c included in the color filter CF can be smaller than the weight percent of the light scattering particles 611 included in the color filter 611b when the light scattering particles 611 are organic scattering particles 611b. When the light scattering particle 611 is the hybrid-type scattering particle 611c, the weight percent of the light scattering particles 611 included in the color filter CF can range from 0.01 to 0.2 wt %, and when the light scattering particle 611 is an organic scattering particle 611b, the weight percent of the light scattering particles 611 included in the color filter CF can range from 0.3 to 0.8 wt %.

Even if the color filter CF includes hybrid-type scattering particles 611c in a relatively low weight percent, due to the hybrid-type structure of the light scattering particles 611c, light scattering characteristics above a desired level can be exhibited.

For example, the thickness d of the color filter CF including hybrid-type scattering particles 611c can be smaller than or equal to the thickness d of the color filter CF including inorganic scattering particles 611a. Referring to FIG. 8, when the light scattering particle 611 is the hybrid-type scattering particle 611c, the thickness d of the first color filter CF1 to the third color filter CF3 can be 2.0 to 3.0 μm, and when the light scattering particle 611 is the inorganic scattering particle 611a, the thickness d of the first color filter CF1 to the third color filter CF3 can be 3.0 to 4.0 μm.

As relatively small hybrid-type scattering particles 611c are included in the plurality of color filters CF, the thickness d of the color filter CF can be reduced. As the thickness d of the color filter CF is reduced, the path of light emitted from the display panel 110 to the outside is shortened, and color mixing can be prevented, thereby increasing light transmittance.

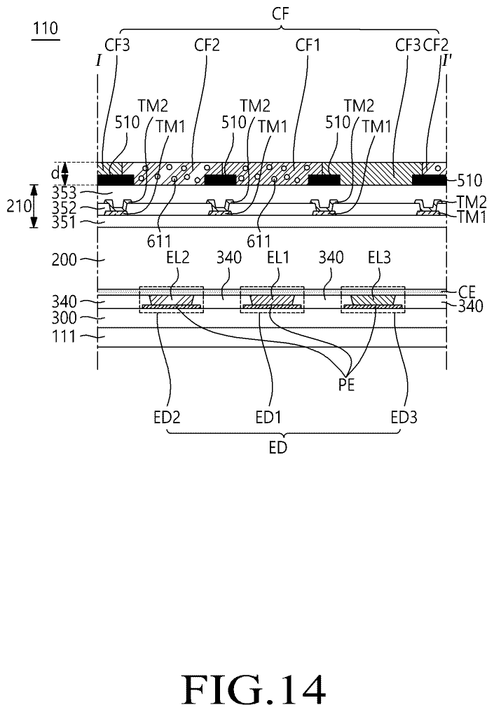

FIGS. 14 to 16 are cross-sectional views illustrating a plurality of subpixels SP taken along line I-I′ of FIG. 4 in a display panel 110 according to embodiments of the disclosure.

FIG. 14 illustrates a change in thickness d depending on whether the light scattering particles 611 are included in the color filter in the display panel 110 according to embodiments of the disclosure.

In the display panel 110 according to embodiments of the disclosure, two or more color filters CF among the plurality of color filters CF can include the light scattering particles 611. The thickness d of the color filter CF including the light scattering particles 611 and the thickness d of the color filter CF not including the light scattering particles 611 can be the same.

Referring to FIG. 14, the light scattering particles 611 can be included in the first color filter CF1 and the second color filter CF2 among the first to third color filters CF1 to CF3. The thickness d of the first color filter CF1 and the second color filter CF2 can be equal to the thickness d of the third color filter CF3 which does not include the light scattering particles 611.

For example, when the light scattering particle 611 is the hybrid-type scattering particle 611c, the thickness d of the first color filter CF1 and the second color filter CF2 including the light scattering particles 611 can be 2.0 to 3.0 μm, and the thickness d of the third color filter CF3 not including the light scattering particles 611 can also be 2.0 to 3.0 μm.

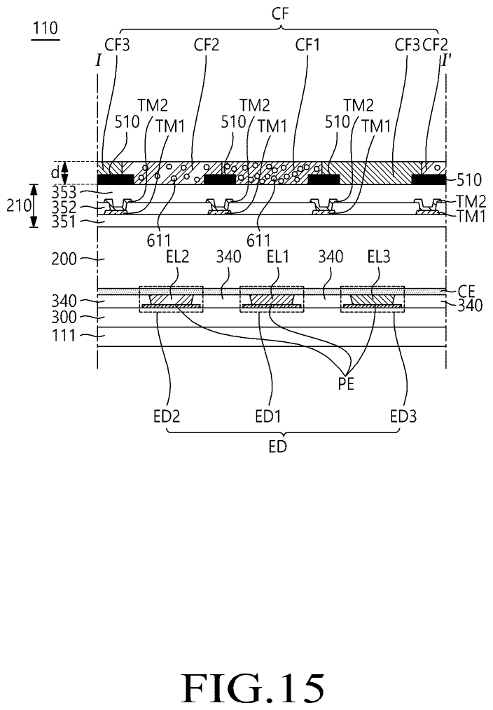

FIG. 15 illustrates a change in thickness d depending on whether the color filter CF includes the light scattering particles 611 in the display panel 110 according to embodiments of the disclosure and a difference in the weight percent of the light scattering particles 611 for each type of the color filter CF.

In the display panel 110 according to embodiments of the disclosure, two or more color filters CF among the plurality of color filters CF can include the light scattering particles 611. The thickness d of the color filter CF including the light scattering particles 611 and the thickness d of the color filter CF not including the light scattering particles 611 can be the same.

Referring to FIG. 15, the thickness d of the first color filter CF1 and the second color filter CF2 including the light scattering particles 611 can be equal to the thickness d of the third color filter CF3 not including the light scattering particles 611.

The weight percent of the light scattering particles 611 included in the first color filter CF1 can be larger than or equal to the weight percent of the light scattering particles 611 included in the second color filter CF2.

For example, when the light scattering particle 611 is the hybrid-type scattering particle 611c, the thickness d of the first color filter CF1 including the light scattering particles 611 can be 2.0 to 3.0 μm, and the weight percent of the light scattering particles 611 in the first color filter CF1 can be 0.1 to 0.2 wt %. The thickness d of the second color filter including the light scattering particles 611 can be 2.0 to 3.0 μm, and the weight percent of the light scattering particles 611 in the second color filter CF2 can be 0.05 to 0.1 wt %. The thickness d of the third color filter CF3 not including the light scattering particles 611 can be 2.0 to 3.0 μm.

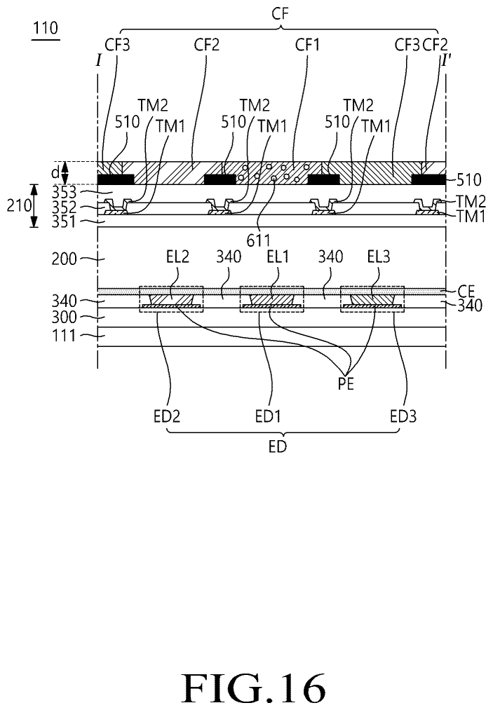

FIG. 16 illustrates a change in thickness d depending on whether the color filter CF includes the light scattering particles 611 in the display panel 110 according to embodiments of the disclosure.

At least one of the plurality of color filters CF in the display panel 110 according to embodiments of the disclosure can include the light scattering particles 611. The thickness d of the color filter CF including the light scattering particles 611 can be equal to the thickness d of the color filter CF not including the light scattering particles 611.

Referring to FIG. 16, the light scattering particles 611 can be included in the first color filter CF1 of the first to third color filters CF1 to CF3. The thickness d of the first color filter CF1 can be equal to the thickness d of the second color filter CF2 and the third color filter CF3, which do not include the light scattering particles 611.

For example, when the light scattering particle 611 is the hybrid-type scattering particle 611c, the thickness d of the first color filter CF1 including the light scattering particles 611 can be 2.0 to 3.0 μm, and the thickness d of the second color filter CF2 and the third color filter CF3 not including the light scattering particles 611 can also be 2.0 to 3.0 μm.

The weight percent of the hybrid-type scattering particles 611c included in the first color filter CF1 can be 0.1 to 0.2 wt %.

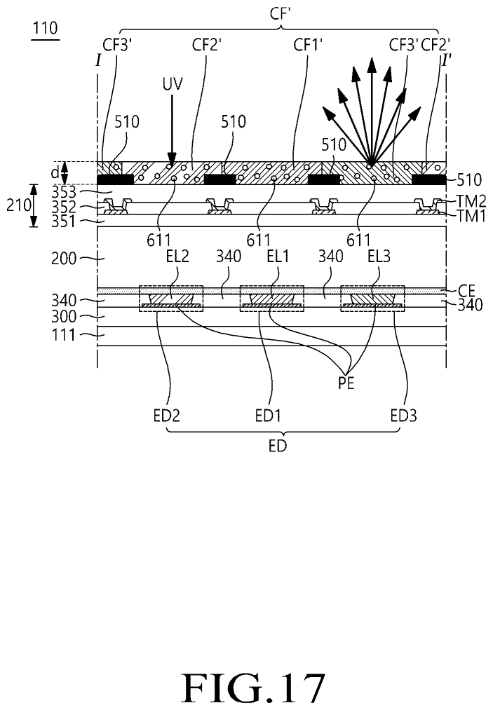

FIG. 17 is a cross-sectional view illustrating a plurality of subpixels SP including a functional color filter CF′ taken along line I-I′ of FIG. 4 in a display panel 110 according to embodiments of the disclosure.

Referring to FIG. 17, a functional color filter CF′ can include a first functional color filter CF1′, a second functional color filter CF2′, and a third functional color filter CF3′.

In the display panel 110 according to embodiments of the disclosure, among a plurality of functional color filters CF′, a functional color filter CF′ including light scattering particles 611 can further include a dispersant different from the light scattering particles 611, and a color filter CF not including light scattering particles 611 may not include a dispersant.

The first functional color filter CF1′ to the third functional color filter CF3′ including the light scattering particles 611 can further include a dispersant.

The dispersant can be used to prevent aggregation of the light scattering particles 611 when mixing the light scattering particles 611 with the color filter photoresist. By preventing aggregation of the light scattering particles 611, light emitted from the display panel 110 can uniformly collide with the light scattering particles 611 and be scattered.

In the display panel 110 according to embodiments of the disclosure, the plurality of functional color filters CF′ can include at least one of an ultraviolet absorber and a light stabilizer.

The light stabilizer is a substance that suppress changes in physical properties caused by photochemical reactions or absorption of light, and is added to prevent discoloration of fibers, or photolysis and discoloration of plastic, and sunscreen can be seen as a kind thereof.

The display panel 110 according to embodiments of the disclosure may not include a polarizer. If the polarizer is not present so that the ultraviolet rays coming from the outside may not be absorbed, some components in the display panel 110 can be damaged by the ultraviolet rays. Therefore, the light resistance of the display panel 110 can be enhanced by applying at least one of an ultraviolet absorber and a light stabilizer to the plurality of functional color filters CF′.

Each of the first functional color filter CF1′ to the third functional color filter CF3′ can include at least one of an ultraviolet absorber and a light stabilizer.

For example, the ultraviolet absorber can be 2-methylphenyl4-methylbenzoate, but the disclosure is not limited thereto.

For example, the light stabilizer can be a Tinuvin-based material, but the disclosure is not limited thereto.

When the first to third functional color filters CF1′ to CF3′ each include an ultraviolet absorber, the weight percent of the ultraviolet absorber can be 1 to 3 wt %. When the first to third functional color filters CF1′ to CF3′ each include a light stabilizer, the weight percent of the light stabilizer can be 0.5 to 1 wt %.

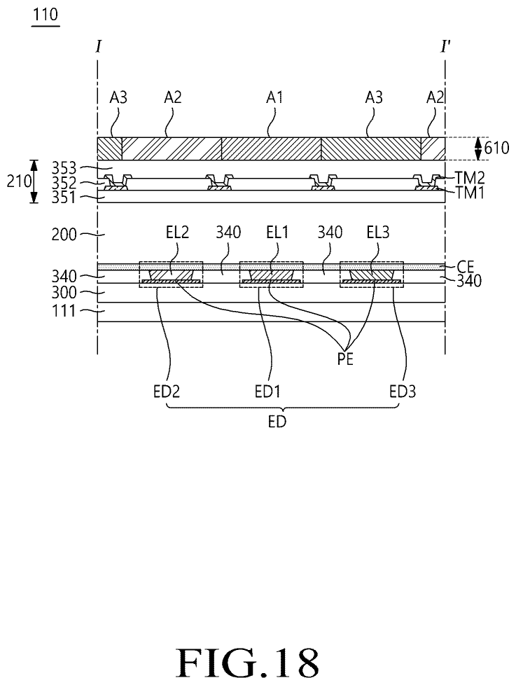

FIG. 18 is a cross-sectional view illustrating a plurality of subpixels taken along line I-I′ of FIG. 4 in a display panel 110 according to embodiments of the disclosure. However, the same description as described above can be omitted.

Referring to FIG. 18, a display panel 110 according to embodiments of the disclosure can include a substrate 111, a first light emitting element ED1 disposed on the substrate 111 and included in a first subpixel SP1, a second light emitting element ED2 disposed on the substrate 111 and included in a second subpixel SP2, a third light emitting element ED3 disposed on the substrate 111 and included in a third subpixel SP3, and a light scattering layer 610 disposed on the first light emitting element ED1, the second light emitting element ED2, and the third light emitting element ED3.

The light scattering layer 610 can include a first area A1 overlapping the first light emitting element ED1, a second area A2 overlapping the second light emitting element ED2, and a third area A3 overlapping the third light emitting element ED3.

At least one of the first area A1, the second area A2, and the third area A3 can include light scattering particles. For example, each of the light scattering particles can include an inorganic material, an organic material, or both an organic material and an organic material.

For example, when some of the first area A1, the second area A2, and the third area A3 include light scattering particles, the height of each of the first area A1, the second area A2, and the third area A3 can vary depending on whether light scattering particles are included.

For example, the first area A1 and the second area A2 can include light scattering particles, and the third area A3 may not include light scattering particles. In this case, the height of each of the first and second areas A1 and A2 can be larger than the height of the third area A3 (see FIG. 10).

As another example, the first area A1 can include light scattering particles, and the second area A2 and the third area A3 may not include light scattering particles. In this case, the height of the first area A1 can be larger than the height of each of the second area A2 and the third area A3 (see FIG. 10).

As another example, when two or more of the first area A1, the second area A2, and the third area A3 include light scattering particles, the weight percent of light scattering particles included in one of the two or more areas can be larger than or equal to the weight percent of light scattering particles included in another area.

For example, the first area A1 and the second area A2 can include light scattering particles, and the third area A3 may not include light scattering particles. In this case, the weight percent of the light scattering particles included in the first area A1 can be larger than or equal to the weight percent of the light scattering particles included in the second area A2.

As another example, the first area A1, the second area A2, and the third area A3 can all include light scattering particles. The weight percent of the light scattering particles included in the first area A1 can be larger than or equal to the weight percent of the light scattering particles included in the second area A2 and the weight percent of the light scattering particles included in the third area A3. The weight percent of the light scattering particles included in the second area A2 can be larger than or equal to the weight percent of the light scattering particles included in the third area A3.

The first light emitted from the first light emitting element ED1 can be incident on the first area A1, the first light emitted from the second light emitting element ED2 can be incident on the second area A2, and the third light emitted from the third light emitting element ED3 can be incident on the third area A3.

The first area A1 can include a first color filter material, and can emit light having a first wavelength as the first light is incident. The second area A2 can include a second color filter material and can emit light of a second wavelength as the second light is incident. The third area A3 can include a third color filter material and can emit light of a third wavelength as the third light is incident.

Among the first wavelength, the second wavelength, and the third wavelength, the second wavelength can be the longest and the third wavelength can be the shortest. The light of the first wavelength emitted in the first area A1, the light of the second wavelength emitted in the second area A2, and the light of the third wavelength emitted in the third area A3 can be different colors of light. For example, the light of the first wavelength can be green light, the light of the second wavelength can be red light, and the light of the third wavelength can be blue light.

For example, the first light emitted from the first light emitting element ED1, the second light emitted from the second light emitting element ED2, and the third light emitted from the third light emitting element ED3 can be different colors of light. For example, the first light can be green light, the second light can be red light, and the third light can be blue light.

As another example, the first light emitted from the first light emitting element ED1, the second light emitted from the second light emitting element ED2, and the third light emitted from the third light emitting element ED3 can all be the same color of light. For example, the first light, the second light, and the third light can be white light.

The foregoing embodiments of the disclosure are briefly described below.

A display panel according to embodiments of the disclosure can comprise a substrate, a plurality of light emitting elements disposed on the substrate, and a plurality of color filters disposed to overlap the plurality of light emitting elements. At least one of the plurality of color filters can include light scattering particles for scattering light incident thereon.

According to the display device according to embodiments of the disclosure, two or more color filters of the plurality of color filters can include the light scattering particles. A weight percent of light scattering particles included in one of the two or more color filters can be equal to or larger than a weight percent of light scattering particles included in another color filter of the two or more color filters.

According to the display device according to embodiments of the disclosure, the two or more color filters can include a first color filter and a second color filter, and light emitted from the first color filter can have a first wavelength, and light emitted from the second color filter can have a second wavelength different from the first wavelength.

According to the display device according to embodiments of the disclosure, the first wavelength can be shorter than the second wavelength, and a weight percent of light scattering particles included in the first color filter can be equal to or larger than a weight percent of light scattering particles included in the second color filter.

According to the display device according to embodiments of the disclosure, the two or more color filters can include a first color filter, a second color filter, and a third color filter. Light emitted from the first color filter can have a first wavelength, light emitted from the second color filter can have a second wavelength different from the first wavelength, and light emitted from the third color filter can have a third wavelength different from the first wavelength and the second wavelength.

According to the display device according to embodiments of the disclosure, among the first wavelength, the second wavelength, and the third wavelength, the third wavelength can be shortest, and the second wavelength can be longest. A weight percent of light scattering particles included in the first color filter can be equal to or larger than a weight percent of light scattering particles included in the second color filter, and the weight percent of light scattering particles included in the second color filter can be equal to or larger than a weight percent of light scattering particles included in the third color filter.

According to the display device according to embodiments of the disclosure, a thickness of each of the plurality of color filters can vary depending on whether light scattering particles are included.

According to the display device according to embodiments of the disclosure, among the plurality of color filters, a color filter including the light scattering particles can have a thickness larger than a thickness of a color filter not including the light scattering particles.

According to the display device according to embodiments of the disclosure, among the plurality of color filters, a color filter including the light scattering particles and a color filter not including the light scattering particles can have the same thickness.

According to the display device according to embodiments of the disclosure, among the plurality of color filters, a color filter including the light scattering particles can further include a dispersant different from the light scattering particle, and a color filter not including the light scattering particles may not include the dispersant.

According to the display device according to embodiments of the disclosure, the plurality of color filters can include at least one of an ultraviolet absorber and a light stabilizer.

According to the display device according to embodiments of the disclosure, each of the plurality of light emitting elements can include a pixel electrode, a light emitting unit disposed on the pixel electrode, and a common electrode disposed on the light emitting unit. The plurality of color filters can include a first color filter overlapping a first light emitting unit included in a first light emitting element among the plurality of light emitting elements, and a second color filter overlapping a second light emitting unit included in a second light emitting element among the plurality of light emitting elements. A wavelength of light emitted from the first light emitting unit can be different from a wavelength of light emitted from the second light emitting unit. A weight percent of light scattering particles included in the first color filter can be different from a weight percent of light scattering particles included in the second color filter.

The display device according to embodiments of the disclosure can further comprise an encapsulation unit disposed on the plurality of light emitting elements and overlapping the two or more color filters having different weight percents of the light scattering particles.

The display device according to embodiments of the disclosure can further comprise a touch unit disposed on the plurality of light emitting elements. The touch unit can include a touch buffer layer, a first touch metal disposed on the touch buffer layer, and a touch protection layer disposed on the first touch metal. The first touch metal can overlap a boundary between the two or more color filters having the different weight percents of the light scattering particles.

The display device according to embodiments of the disclosure can further comprise a black matrix disposed on the touch unit, disposed to overlap the first touch metal, and disposed on the boundary between the two or more color filters having the different weight percents of the light scattering particles.

The display device according to embodiments of the disclosure can further comprise a bank disposed between the first and second light emitting units and overlapping a boundary between the first and second color filters having different weight percents of the light scattering particles.

According to the display device according to embodiments of the disclosure, the light scattering particle includes an organic material.

According to the display device according to embodiments of the disclosure, a thickness of the at least one of the plurality of color filters can be 4.0 to 5.0 μm, and a weight percent of the light scattering particles included in the at least one of the plurality of color filters can be 0.3 to 0.8 wt %.

According to the display device according to embodiments of the disclosure, the light scattering particle can include an inorganic material.

According to the display device according to embodiments of the disclosure, a thickness of the at least one of the plurality of color filters can be 3.0 to 4.0 μm, and a weight percent of the light scattering particles included in the at least one of the plurality of color filters can be 0.01 to 0.2 wt %.

According to the display device according to embodiments of the disclosure, the light scattering particle can have a core-shell structure including a shell including an inorganic material and a core disposed in the shell and including an organic material.

According to the display device according to embodiments of the disclosure, in the light scattering particle, a weight percent of the inorganic material can be equal to or smaller than a weight percent of the organic material.

According to the display device according to embodiments of the disclosure, a thickness of the at least one of the plurality of color filters can be 2.0 to 3.0 μm, and a weight percent of the light scattering particles included in the at least one of the plurality of color filters can be 0.01 to 0.2 wt %.

According to the display device according to embodiments of the disclosure, the first color filter can have a thickness equal to that of the second color filter.

According to the display device according to embodiments of the disclosure, the first color filter can a thickness equal to those of the second color filter and the third color filter.

A display device according to embodiments of the disclosure can comprise a substrate, a plurality of subpixels disposed on the substrate, a first light emitting element disposed on the substrate and included in a first subpixel of the plurality of subpixels, a second light emitting element disposed on the substrate and included in a second subpixel of the plurality of subpixels, a third light emitting element disposed on the substrate and included in a third subpixel of the plurality of subpixels, and a light scattering layer disposed on the first light emitting element, the second light emitting element, and the third light emitting element.

The light scattering layer can include a first area overlapping the first light emitting element, a second area overlapping the second light emitting element, and a third area overlapping the third light emitting element.

At least one of the first area, the second area, and the third area can include light scattering particles for scattering light incident thereon.

For example, a height of each of the first area, the second area, and the third area can vary depending on whether the light scattering particles are included.

Among the first area, the second area and the third area, a height of an area including the light scattering particles can be larger than a height of an area not including the light scattering particles.

As another example, when two or more areas of the first area, the second area, and the third area include the light scattering particles, a weight percent of the light scattering particles included in one of the two or more areas can be different from a weight percent of the light scattering particles included in another area of the two or more areas.

The first area can include a first color filter material and emit light of a first color as first light is incident. The second area can include a second color filter material and emit light of a second color as second light is incident. The third area can include a third color filter material and emit light of a third color as third light is incident.

The light of the first wavelength can be green light, the light of the second wavelength can be red light, and the light of the third wavelength can be blue light.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

What is claimed:

1. A display device, comprising:
a substrate;
a plurality of light emitting elements disposed on the substrate; and
a plurality of color filters disposed to overlap the plurality of light emitting elements,
wherein at least one of the plurality of color filters includes light scattering particles for scattering light incident thereon.

2. The display device of claim 1, wherein two or more color filters of the plurality of color filters include the light scattering particles, and
wherein a weight percent of light scattering particles included in one of the two or more color filters is equal to or larger than a weight percent of light scattering particles included in another color filter of the two or more color filters.

3. The display device of claim 2, wherein the two or more color filters include a first color filter and a second color filter,
wherein light emitted from the first color filter has a first wavelength, and light emitted from the second color filter has a second wavelength different from the first wavelength,
wherein the first wavelength is shorter than the second wavelength, and
wherein a weight percent of light scattering particles included in the first color filter is equal to or larger than a weight percent of light scattering particles included in the second color filter.

4. The display device of claim 2, wherein the two or more color filters include a first color filter, a second color filter, and a third color filter,
wherein light emitted from the first color filter has a first wavelength, light emitted from the second color filter has a second wavelength different from the first wavelength, and light emitted from the third color filter has a third wavelength different from each of the first wavelength and the second wavelength,
wherein among the first wavelength, the second wavelength, and the third wavelength, the third wavelength is shortest, and the second wavelength is longest, and
wherein a weight percent of light scattering particles included in the first color filter is equal to or larger than a weight percent of light scattering particles included in the second color filter, and the weight percent of light scattering particles included in the second color filter is equal to or larger than a weight percent of light scattering particles included in the third color filter.

5. The display device of claim 1, wherein among the plurality of color filters, a color filter including the light scattering particles has a thickness that is equal to or larger than a thickness of a color filter not including the light scattering particles.

6. The display device of claim 1, wherein among the plurality of color filters, a color filter including the light scattering particles further includes a dispersant different from the light scattering particles, and a color filter not including the light scattering particles does not include the dispersant.

7. The display device of claim 1, wherein the plurality of color filters include at least one of an ultraviolet absorber and a light stabilizer.

8. The display device of claim 1, wherein each of the plurality of light emitting elements includes:
a pixel electrode;
a light emitting unit disposed on the pixel electrode; and
a common electrode disposed on the light emitting unit, and
wherein the plurality of color filters include:
a first color filter overlapping a first light emitting unit included in a first light emitting element among the plurality of light emitting elements; and
a second color filter overlapping a second light emitting unit included in a second light emitting element among the plurality of light emitting elements,
wherein a wavelength of light emitted from the first light emitting unit is different from a wavelength of light emitted from the second light emitting unit, and
wherein a weight percent of light scattering particles included in the first color filter is different from a weight percent of light scattering particles included in the second color filter.

9. The display device of claim 2, further comprising an encapsulation unit disposed on the plurality of light emitting elements and overlapping the two or more color filters having different weight percents of the light scattering particles.

10. The display device of claim 2, further comprising a touch unit disposed on the plurality of light emitting elements,
wherein the touch unit includes:
a touch buffer layer;
a first touch metal disposed on the touch buffer layer; and
a touch protection layer disposed on the first touch metal, and
wherein the first touch metal overlaps a boundary between the two or more color filters having the different weight percents of the light scattering particles.

11. The display device of claim 10, further comprising a black matrix disposed on the touch unit, disposed to overlap the first touch metal, and disposed on the boundary between the two or more color filters having the different weight percents of the light scattering particles.

12. The display device of claim 8, further comprising a bank disposed between the first and second light emitting units and overlapping a boundary between the first and second color filters having different weight percents of the light scattering particles.

13. The display device of claim 1, wherein the light scattering particles include an organic material.

14. The display device of claim 1, wherein the light scattering particles include an inorganic material, and
wherein each of the light scattering particles has a core-shell structure including a shell including an inorganic material and a core disposed in the shell and including an organic material.

15. The display device of claim 14, wherein in each light scattering particle, a weight percent of the inorganic material is equal to or smaller than a weight percent of the organic material.

16. The display device of claim 3, wherein the first color filter has a thickness equal to a thickness of the second color filter.

17. The display device of claim 4, wherein the first color filter has a thickness equal to thicknesses of the second color filter and the third color filter.

18. A display device, comprising:
a plurality of subpixels disposed on a substrate and including a first subpixel, a second subpixel and a third subpixel;
a first light emitting element disposed on the substrate and included in the first subpixel;
a second light emitting element disposed on the substrate and included in the second subpixel;
a third light emitting element disposed on the substrate and included in the third subpixel; and
a light scattering layer disposed on the first light emitting element, the second light emitting element, and the third light emitting element,
wherein the light scattering layer includes a first area overlapping the first light emitting element, a second area overlapping the second light emitting element, and a third area overlapping the third light emitting element,
wherein at least one of the first area, the second area, and the third area includes light scattering particles configured to scatter light incident thereon, and
wherein a height of each of the first area, the second area, and the third area varies depending on whether the light scattering particles are included.

19. The display device of claim 18, wherein among the first area, the second area and the third area, a height of an area including the light scattering particles is larger than a height of an area not including the light scattering particles.

20. The display device of claim 18, wherein when two or more areas of the first area, the second area, and the third area include the light scattering particles, a weight percent of the light scattering particles included in one of the two or more areas is different from a weight percent of the light scattering particles included in another area of the two or more areas,
wherein the first area includes a first color filter material and is configured to emit light of a first wavelength,
wherein the second area includes a second color filter material and is configured to emit light of a second wavelength, and
wherein the third area includes a third color filter material and is configured to emit light of a third wavelength.
